(19) United States
(12) Patent Application Publication
(10) Pub. No.: US 2025/0314965 A1
(43) Pub. Date: Oct. 9, 2025

(54) PHOTOSENSITIVE COMPOSITION, CURED FILM, PHOTOSENSITIVE TRANSFER MATERIAL, FILM, AND LAMINATE

(71) Applicant: FUJIFILM CORPORATION, Tokyo (JP)

(72) Inventors: Masaya SUZUKI, Kanagawa (JP); Keigo UEKI, Kanagawa (JP)

(21) Appl. No.: 19/241,400

(22) Filed: Jun. 18, 2025

Related U.S. Application Data
(63) Continuation of application No. PCT/JP2023/041783, filed on Nov. 21, 2023.

(30) Foreign Application Priority Data
Dec. 28, 2022 (JP) 2022-212020

(51) Int. Cl. G03F 7/028; C08F 265/06; G03F 7/00; G03F 7/033; G03F 7/16

(52) U.S. Cl. CPC G03F 7/028; C08F 265/06; G03F 7/0007; G03F 7/033; G03F 7/161; G03F 7/168

(57) ABSTRACT

Provided are a photosensitive composition containing a blocked isocyanate compound, in which a blocked group of the blocked isocyanate compound includes an aromatic ring, and the aromatic ring is bonded to a carbonyl group included in the blocked isocyanate compound through an oxygen atom; a cured film; a photosensitive transfer material; a film; a touch panel; and a laminate.

### CROSS-REFERENCE TO RELATED APPLICATIONS

This application is a continuation application of International Application No. PCT/JP2023/041783, filed Nov. 21, 2023, which is incorporated herein by reference. Further, this application claims priority from Japanese Patent Application No. 2022-212020, filed Dec. 28, 2022, which is incorporated herein by reference.

### BACKGROUND OF THE INVENTION

### 1. Field of the Invention

The present disclosure relates to a photosensitive composition, a cured film, a photosensitive transfer material, a film, and a laminate.

### 2. Description of the Related Art

In recent years, in an electronic apparatus such as a mobile phone, a car navigator, a personal computer, a ticket vending machine, or a terminal of the bank, a tablet-type input device is disposed on a surface of a liquid crystal device or the like. In such an electronic apparatus, while referring to an instruction image displayed in an image display region of a liquid crystal device, information corresponding to the instruction image can be input by touching a portion where the instruction image is displayed, with a finger or a touch pen.

The input device described above (hereinafter, also referred to as “touch panel”) includes a resistance film-type input device, a capacitive input device, and the like. The capacitive input device is advantageous in that a translucent conductive film may be simply formed on one sheet of a substrate. As such a capacitive input device, for example, there is a device in which electrode patterns are extended in directions intersecting each other, and which detects an input position by detecting a change of electrostatic capacity between electrodes, in a case where a finger or the like is touched.

In order to protect electrode patterns or lead wire (for example, metal wire such as copper wire) put together on a frame portion of the capacitive input device, a transparent resin layer is provided. A photosensitive resin composition is used as a material for forming such a transparent resin layer.

For example, JP2016-181083A discloses a photosensitive resin composition containing a binder polymer, a photopolymerizable compound having an ethylenically unsaturated group, a photopolymerization initiator, and a blocked isocyanate.

In addition, JP2017-044965A discloses a photosensitive resin composition containing a binder polymer, a photopolymerizable compound having an ethylenically unsaturated group, a photopolymerization initiator, and a compound capable of reacting with an acid by heating, such as a blocked isocyanate.

In addition, WO2018/105313A discloses a photosensitive resin composition containing a binder polymer, an ethylenically unsaturated compound, a photopolymerization initiator, and a compound capable of reacting with an acid by heating, such as a blocked isocyanate.

Furthermore, WO2020/059260A discloses a photosensitive resin composition containing a binder polymer, an ethylenically unsaturated compound not having a blocked isocyanate group, a photopolymerization initiator, and a blocked isocyanate compound, in which the blocked isocyanate compound has a carboxylic acid group.

### SUMMARY OF THE INVENTION

In a case where the blocked isocyanate is contained as in the photosensitive resin compositions disclosed in JP2016-181083A, JP2017-044965A, WO2018/105313A, and WO2020/059260A, a carboxy group (—COOH) and the like, contained in the binder polymer, are consumed during curing of the photosensitive resin composition, hydrophobicity of a cured film and the like is improved, and thus reliability of a device and the like tends to be improved.

However, since a large amount of phosgene or the like is used in the synthesis of the blocked isocyanate contained in the photosensitive resin compositions known in the related art, a large amount of chlorine, chloride ion, or the like is mixed. Therefore, in a case where the device and the like are irradiated with ultraviolet rays (UV rays) or the like, dissolved oxygen in a film formed on a metal wire such as silver and copper is activated due to the presence of chlorine, chloride ion, or the like, and an oxidation reaction occurs, which may reduce the reliability of the device and the like (for example, surface electrical resistance increases).

The present disclosure has been made in view of such circumstances, and an object to be achieved by one embodiment of the present disclosure is to provide a photosensitive composition capable of suppressing an oxidation reaction due to UV irradiation and improving reliability.

An object to be achieved by another embodiment of the present disclosure is to provide a cured film obtained by curing the above-described photosensitive composition.

An object to be achieved by another embodiment of the present disclosure is to provide a photosensitive transfer material using the above-described photosensitive composition.

An object to be achieved by another embodiment of the present disclosure is to provide a film capable of improving reliability.

An object to be achieved by another embodiment of the present disclosure is to provide a laminate capable of improving reliability.

The means for achieving the above-described objects includes the following aspects.

<1> A photosensitive composition comprising:
a blocked isocyanate compound,
in which a blocked group of the blocked isocyanate compound includes an aromatic ring, and
the aromatic ring is bonded to a carbonyl group included in the blocked isocyanate compound through an oxygen atom.
<2> The photosensitive composition according to <1>, in which the blocked isocyanate compound has a polymerizable group.
<3> The photosensitive composition according to <1> or <2>, in which the aromatic ring is a benzene ring.
<4> The photosensitive composition according to any one of <1> to <3>, in which the blocked isocyanate compound has a structure represented by General Formula (1).

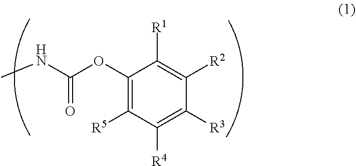

In General Formula (1),
R¹ to R⁵ each independently represent a hydrogen atom, an alkyl group, an alkoxy group, or an alkoxycarbonyl group.
<5> The photosensitive composition according to any one of <1> to <4>,
in which the blocked isocyanate compound is represented by General Formula (2).

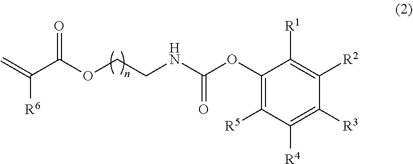

In General Formula (2),
R¹ to R⁵ each independently represent a hydrogen atom, an alkyl group, an alkoxy group, or an alkoxycarbonyl group,
R⁶ represents a hydrogen atom, an alkyl group, or an alkoxy group, and
n represents an integer of 0 to 10.
<6> The photosensitive composition according to any one of <1> to <5>,
in which a content of the blocked isocyanate compound is 3% by mass to 20% by mass with respect to a total solid content of the photosensitive composition.
<7> The photosensitive composition according to any one of <1> to <6>,
in which the photosensitive composition contains no halide ion, or
the photosensitive composition contains a halide ion and a content of the halide ion is 5.0 ppm by mass with respect to a total solid content of the photosensitive composition.
<8> The photosensitive composition according to any one of <1> to <7>, further comprising:
a binder polymer;
a polymerizable compound; and
a polymerization initiator.
<9> The photosensitive composition according to <8>,
in which the binder polymer includes a resin having a carboxy group.
<10> The photosensitive composition according to <9>,
in which the binder polymer includes a (meth)acrylic resin having a carboxy group.
<11> The photosensitive composition according to <4>,
in which the photosensitive composition contains a binder polymer, a polymerizable compound, and a polymerization initiator, and
the binder polymer includes a (meth)acrylic resin having a carboxy group.
<12> A cured film obtained by curing the photosensitive composition according to any one of <1> to <11>.
<13> A photosensitive transfer material comprising:
a temporary support; and
a photosensitive layer containing the photosensitive composition according to any one of <1> to <11>.
<14> A laminate comprising, in the following order:
a substrate having a surface on which a layer containing a metal is provided; and
the cured film according to <12>.
<15> The laminate according to <14>,
in which the laminate is a touch panel.

According to one embodiment of the present disclosure, a photosensitive composition capable of suppressing an oxidation reaction due to UV irradiation and improving reliability is provided.

According to another embodiment of the present disclosure, a cured film obtained by curing the above-described photosensitive composition is provided.

According to another embodiment of the present disclosure, a photosensitive transfer material using the above-described photosensitive composition is provided.

According to another embodiment of the present disclosure, a manufacturing method of the above-described photosensitive transfer material is provided.

According to another embodiment of the present disclosure, a film capable of improving reliability is provided.

According to another embodiment of the present disclosure, a laminate capable of improving reliability is provided.

### BRIEF DESCRIPTION OF THE DRAWINGS

FIG. 1 is a schematic cross-sectional view showing an example of a photosensitive transfer material according to the present disclosure.

FIG. 2 is a schematic cross-sectional view showing another example of the photosensitive transfer material according to the present disclosure.

FIG. 3 is a schematic cross-sectional view showing still another example of the photosensitive transfer material according to the present disclosure.

FIG. 4 is a schematic cross-sectional view showing one specific example of the touch panel according to the present disclosure.

FIG. 5 is a schematic cross-sectional view showing another specific example of the touch panel according to the present disclosure.

FIG. 6 is a schematic plan view showing still another specific example of the touch panel according to the present disclosure.

FIG. 7 is a cross-sectional view taken along a line A-A of FIG. 6.

FIG. 8 is a schematic cross-sectional view of a UV light resistance test sample 400 produced in a UV light resistance test.

### DESCRIPTION OF THE PREFERRED EMBODIMENTS

Hereinafter, the content of the present disclosure will be described in detail. The configuration requirements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this present disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In addition, in the present disclosure, “% by mass” is identical to “% by weight” and “part by mass” is identical to “part by weight”.

Furthermore, in the present disclosure, a combination of two or more preferred aspects is the more preferred aspects.

In the present disclosure, in a case where a plurality of substances corresponding to components are present in a composition, an amount of each component in the composition means a total amount of the plurality of substances present in the composition, unless otherwise noted.

In the present disclosure, a term “step” not only includes an independent step, but also includes a step, in a case where the step may not be distinguished from the other step, as long as the expected object of the step is achieved.

In the present disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

In addition, a weight-average molecular weight (Mw) and a number-average molecular weight (Mn) in the present disclosure are molecular weights in terms of polystyrene used as a standard substance, which are detected by using a solvent tetrahydrofuran (THF), a differential refractometer, and a gel permeation chromatography (GPC) analysis apparatus using TSKgel GMHxL, TSKgel G4000HxL, and TSKgel G2000HxL (all product names manufactured by Tosoh Corporation) as columns, unless otherwise specified.

In the present disclosure, unless otherwise specified, a molecular weight of a compound having a molecular weight distribution is the weight-average molecular weight.

In the present disclosure, unless otherwise specified, a ratio of constitutional units of a polymer is a molar ratio.

In the present disclosure, unless otherwise specified, a refractive index is a value at a wavelength of 550 nm measured at 25° C. with an ellipsometer.

In the present disclosure, “total solid content” means the total mass of components other than the solvent, contained in the composition or the like.

Hereinafter, the present disclosure will be described in detail.

### (Photosensitive Composition)

The photosensitive composition according to the present disclosure contains a blocked isocyanate compound (hereinafter, also referred to as “specific blocked isocyanate compound”),
in which a blocked group of the blocked isocyanate compound includes an aromatic ring, and
the aromatic ring is bonded to a carbonyl group included in the blocked isocyanate compound through an oxygen atom.

The use application of the photosensitive composition according to the present disclosure is not particularly limited, but it is preferably used for forming a protective film of a metal nanowire electrode, and more preferably used for forming a protective film of a silver nanowire electrode.

### <Specific Blocked Isocyanate Compound>

The blocked group of the specific blocked isocyanate compound includes an aromatic ring, and the aromatic ring is bonded to the carbonyl group included in the specific blocked isocyanate compound through an oxygen atom.

In the present disclosure, the “blocked isocyanate compound” refers to “compound having a structure in which a blocked group is bonded to an isocyanate group of isocyanate”.

The aromatic ring included in the blocked group is not particularly limited, and examples thereof include a benzene ring, a naphthalene ring, an anthracene ring, a pyridine ring, a pyrrole ring, and a pyrene ring. Among these, from the viewpoint of suppressing the oxidation reaction due to UV irradiation and improving the reliability, a benzene ring is preferable.

The aromatic ring may have a substituent, and from the viewpoint of the above-described reliability, it is preferable to have one or more substituents selected from an alkyl group, an alkoxy group, and an alkoxycarbonyl group; more preferable to have one or more substituents selected from an alkyl group having 1 to 6 carbon atoms (also referred to as “number of carbon atoms”), an alkoxy group having 1 to 6 carbon atoms, and an alkoxycarbonyl group having 2 to 6 carbon atoms; still more preferable to have one or more substituents selected from an alkyl group having 1 to 3 carbon atoms, an alkoxy group having 1 to 3 carbon atoms, and an alkoxycarbonyl group having 2 to 4 carbon atoms; and particularly preferable to have an alkoxycarbonyl group having 2 to 4 carbon atoms.

Examples of the alkyl group include a methyl group, an ethyl group, and a propyl group.

Examples of the alkoxy group include a methoxy group, an ethoxy group, and a propoxy group.

Examples of the alkoxycarbonyl group include a methoxycarbonyl group, an ethoxycarbonyl group, and a propoxycarbonyl group.

From the viewpoint of reducing brittleness of a photosensitive layer in a photosensitive transfer material, the specific blocked isocyanate compound preferably has a polymerizable group.

Examples of the polymerizable group include a (meth)acryloxy group, a (meth)acrylamide group, an ethylenically unsaturated group such as a styryl group, and an epoxy group such as a glycidyl group. Among these, from the viewpoint of development speed and reactivity, the polymerizable group is preferably an ethylenically unsaturated group, and more preferably a (meth)acryloxy group.

From the viewpoint of reducing brittleness of the photosensitive layer in the photosensitive transfer material and viewpoint of improving adhesiveness to an object to be transferred, the specific blocked isocyanate compound preferably has an isocyanurate structure.

The specific blocked isocyanate compound having an isocyanurate structure can be obtained, for example, by isocyanurate-forming and protecting hexamethylene diisocyanate.

From the viewpoint of suppressing the oxidation reaction due to UV irradiation and improving the reliability, the specific blocked isocyanate compound preferably has a structure represented by General Formula (1).

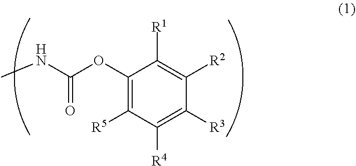

In General Formula (1),
R¹ to R⁵ each independently represent a hydrogen atom, an alkyl group, an alkoxy group, or an alkoxycarbonyl group.

It is preferable that at least one of R¹, . . . , or R⁵ is an alkyl group, an alkoxy group, or an alkoxycarbonyl group; more preferable that at least one of R¹, . . . , or R⁵ is an alkyl group having 1 to 6 carbon atoms, an alkoxy group having 1 to 6 carbon atoms, or an alkoxycarbonyl group having 1 to 6 carbon atoms; still more preferable that at least one of R¹, . . . , or R⁵ is an alkyl group having 1 to 3 carbon atoms, an alkoxy group having 1 to 3 carbon atoms, or an alkoxycarbonyl group having 1 to 3 carbon atoms; and particularly preferable that at least one of R¹, . . . , or R⁵ is an alkoxycarbonyl group having 1 to 3 carbon atoms.

From the viewpoint of suppressing the oxidation reaction due to UV irradiation and improving the reliability, and from the viewpoint of improving reliability of a device or the like in a case of being left to stand in a high-temperature and high-humidity environment (suppressing an increase in surface electrical resistance), at least R¹ in R¹ to R⁵ is preferably an alkyl group, an alkoxy group, or an alkoxycarbonyl group, more preferably an alkyl group having 1 to 6 carbon atoms, an alkoxy group having 1 to 6 carbon atoms, or an alkoxycarbonyl group having 2 to 6 carbon atoms, still more preferably an alkyl group having 1 to 3 carbon atoms, an alkoxy group having 1 to 3 carbon atoms, or an alkoxycarbonyl group having 2 to 4 carbon atoms, and particularly preferably an alkoxycarbonyl group having 2 to 4 carbon atoms.

The specific blocked isocyanate compound may have only one or two or more of the structures represented by General Formula (1).

From the viewpoint of suppressing the oxidation reaction due to UV irradiation and improving the reliability, the specific blocked isocyanate compound is preferably represented by General Formula (2).

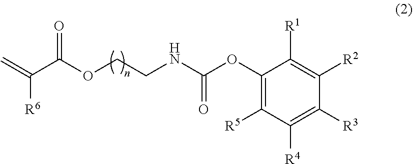

In General Formula (2),
R¹ to R⁵ each independently represent a hydrogen atom, an alkyl group, an alkoxy group, or an alkoxycarbonyl group,
R⁶ represents a hydrogen atom, an alkyl group, or an alkoxy group, and n represents an integer of 0 to 10.

Preferred aspects of R¹ to R⁵ are the same as those of General Formula (1), and thus the description thereof will not be repeated here.

From the viewpoint of suppressing the oxidation reaction due to UV irradiation and improving the reliability, R⁶ is preferably a hydrogen atom, an alkyl group having 1 to 6 carbon atoms, or an alkoxy group having 1 to 6 carbon atoms; more preferably a hydrogen atom, an alkyl group having 1 to 3 carbon atoms, or an alkoxy group having 1 to 3 carbon atoms; and still more preferably a hydrogen atom or an alkyl group having 1 to 3 carbon atoms.

From the viewpoint of the above-described reliability, n is preferably an integer of 1 to 5, and more preferably an integer of 1 to 3.

Specific examples of the specific blocked isocyanate compound include the following compounds. The specific blocked isocyanate compound is not limited to the following compounds.

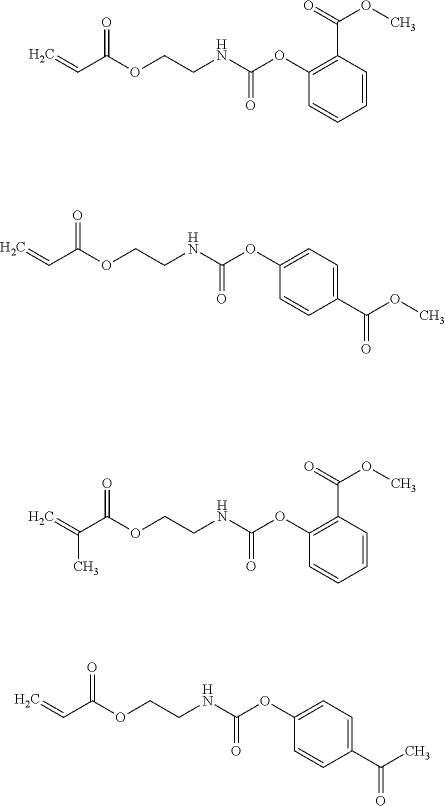

A dissociation temperature of the blocked group of the specific blocked isocyanate compound is not particularly limited, but is preferably 100° C. to 180° C. and more preferably 110° C. to 160° C.

The dissociation temperature in the present disclosure means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

From the viewpoint of reducing brittleness of the photosensitive layer in the photosensitive transfer material, a molecular weight of the specific blocked isocyanate compound is preferably 200 to 500, and more preferably 250 to 400.

From the viewpoint of suppressing the oxidation reaction due to UV irradiation and improving the reliability, and viewpoint of reducing brittleness of the photosensitive layer in the photosensitive transfer material, a content of the specific blocked isocyanate compound is preferably 3% by mass to 20% by mass, more preferably 5% by mass to 17% by mass, and still more preferably 6% by mass to 16% by mass with respect to the total solid content of the photosensitive composition.

### <Binder Polymer>

The photosensitive composition according to the present disclosure can contain a binder polymer.

From the viewpoint of adhesiveness to a layer containing a metal and strength of a resin layer to be obtained after pattern formation, it is preferable that the photosensitive composition according to the present disclosure contains a binder polymer and a polymerizable compound.

In addition, in a case where the photosensitive composition does not contain a polymerizable compound, the binder polymer preferably includes a binder polymer having a polymerizable group (preferably, an ethylenically unsaturated group).

Examples of the binder polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and an acid anhydride.

From the viewpoint of excellent alkali developability and film formability, examples of one suitable aspect of the binder polymer include a (meth)acrylic resin.

From the viewpoint of developability, the binder polymer preferably includes an alkali-soluble resin, and is more preferably an alkali-soluble resin.

In the present disclosure, the “alkali-soluble” means that solubility in 100 g of an aqueous solution of 1% by mass sodium carbonate at 22° C. is 0.1 g or more.

From the viewpoint of developability, for example, the binder polymer is preferably a binder polymer having an acid value of 60 mgKOH/g or more, and more preferably an alkali-soluble resin having an acid value of 60 mgKOH/g or more.

In addition, from the viewpoint of easily forming a firm film by thermally crosslinking with a crosslinking component by heating, the binder polymer preferably includes a resin having a carboxy group (so-called carboxy group-containing resin), more preferably a carboxy group-containing resin, still more preferably a carboxy group-containing resin having an acid value of 60 mgKOH/g or more, and particularly preferably a (meth)acrylic resin having an acid value of 60 mgKOH/g or more and having a carboxy group (so-called carboxy group-containing (meth)acrylic resin).

In a case where the binder polymer is a resin having a carboxy group, for example, the three-dimensional crosslinking density can be increased by adding blocked isocyanate and thermally crosslinking. In addition, in a case where the carboxy group of the resin having a carboxy group is dehydrated and hydrophobized, the reliability of the device and the like can be improved.

The carboxy group-containing (meth)acrylic resin (hereinafter, also referred to as “specific polymer A”) having an acid value of 60 mgKOH/g or more is not particularly limited as long as the above-described conditions of acid value are satisfied, and a known (meth)acrylic resin can be appropriately selected and used.

For example, a carboxy group-containing (meth)acrylic resin having an acid value of 60 mgKOH/g or more, among polymers described in paragraph 0025 of JP2011-95716A, a carboxy group-containing (meth)acrylic resin having an acid value of 60 mgKOH/g or more, among polymers described in paragraphs 0033 to 0052 of JP2010-237589A, and the like can be preferably used as the specific polymer A in the present disclosure.

Here, the (meth)acrylic resin refers to a resin containing at least one of a constitutional unit derived from (meth)acrylic acid or a constitutional unit derived from (meth)acrylic acid ester.

The total proportion of the constitutional unit derived from (meth)acrylic acid and the constitutional unit derived from (meth)acrylic acid ester in the (meth)acrylic resin is preferably 30 mol % or more and more preferably 50 mol % or more. Similarly, the total proportion is preferably 30% by mass or more, and more preferably 50% by mass or more.

The polymer A may have a linear structure, a branched structure, or an alicyclic structure in the side chain.

The copolymerization ratio of the monomer having a carboxy group in the specific polymer A is preferably 5% by mass to 50% by mass, more preferably 5% by mass to 40% by mass, and still more preferably 10% by mass to 30% by mass with respect to 100% by mass of the specific polymer A.

In addition, from the viewpoint of moisture permeability and hardness after curing, the binder polymer (particularly, the specific polymer A) preferably has a constitutional unit having an aromatic ring.

Examples of a monomer forming the constitutional unit having an aromatic ring include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, styrene trimer, and the like). Among these, a monomer having an aralkyl group or styrene is preferable.

Examples of the aralkyl group include a substituted or unsubstituted phenylalkyl group, and a substituted or unsubstituted benzyl group is preferable.

Examples of a monomer having a phenylalkyl group other than a benzyl group include phenylethyl (meth)acrylate.

Examples of a monomer having a benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

The constitutional unit having an aromatic ring is preferably a constitutional unit derived from a styrene compound.

In a case where the binder polymer includes the constitutional unit having an aromatic ring, a content of the constitutional unit having an aromatic ring is preferably 5% by mass to 90% by mass, more preferably 10% by mass to 70% by mass, and still more preferably 20% by mass to 50% by mass with respect to the total mass of the binder polymer.

In addition, from the viewpoint of tackiness and hardness after curing, the binder polymer (particularly, the specific polymer A) preferably has a constitutional unit having an aliphatic cyclic skeleton. The aliphatic cyclic skeleton may be a monocyclic skeleton or a polycyclic skeleton.

Examples of a monomer forming the constitutional unit having an aliphatic cyclic skeleton include dicyclopentanyl (meth)acrylate, cyclohexyl (meth)acrylate, and isobornyl (meth)acrylate.

Examples of an aliphatic ring included in the constitutional unit having an aliphatic cyclic skeleton include a cyclohexane ring, an isophorone ring, and a tricyclodecane ring.

Among these, a tricyclodecane ring is particularly preferable as the aliphatic ring included in the constitutional unit having an aliphatic cyclic skeleton.

In a case where the binder polymer includes the constitutional unit having an aliphatic cyclic skeleton, a content of the constitutional unit having an aliphatic cyclic skeleton is preferably 5% by mass to 90% by mass, more preferably 10% by mass to 80% by mass, and still more preferably 20% by mass to 70% by mass with respect to the total mass of the binder polymer.

In addition, from the viewpoint of tackiness and hardness after curing, the binder polymer (particularly, the specific polymer A) preferably has a reactive group.

As the reactive group, a radically polymerizable group is preferable, and an ethylenically unsaturated group is more preferable. In addition, in a case where the binder polymer (particularly, the specific polymer A) has an ethylenically unsaturated group, the binder polymer (particularly, the specific polymer A) preferably includes a constitutional unit having an ethylenically unsaturated group in the side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryloyl group and more preferably a (meth)acryloxy group.

In a case where the binder polymer includes the constitutional unit having an ethylenically unsaturated group, a content of the constitutional unit having an ethylenically unsaturated group is preferably 5% by mass to 70% by mass, more preferably 10% by mass to 50% by mass, and still more preferably 20% by mass to 40% by mass with respect to the total mass of the binder polymer.

Examples of a method for introducing the reactive group into the specific polymer A include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, or the like.

Preferred examples of the method for introducing the reactive group into the specific polymer A include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain (for example, a compound A and compound B shown below) can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the specific polymer A, the following compounds A to C are preferable, and the compound B is more preferable. A content ratio of each constitutional unit shown below can be appropriately changed according to the purpose. In addition, in the compounds A to C, each copolymerization ratio is a mass ratio.

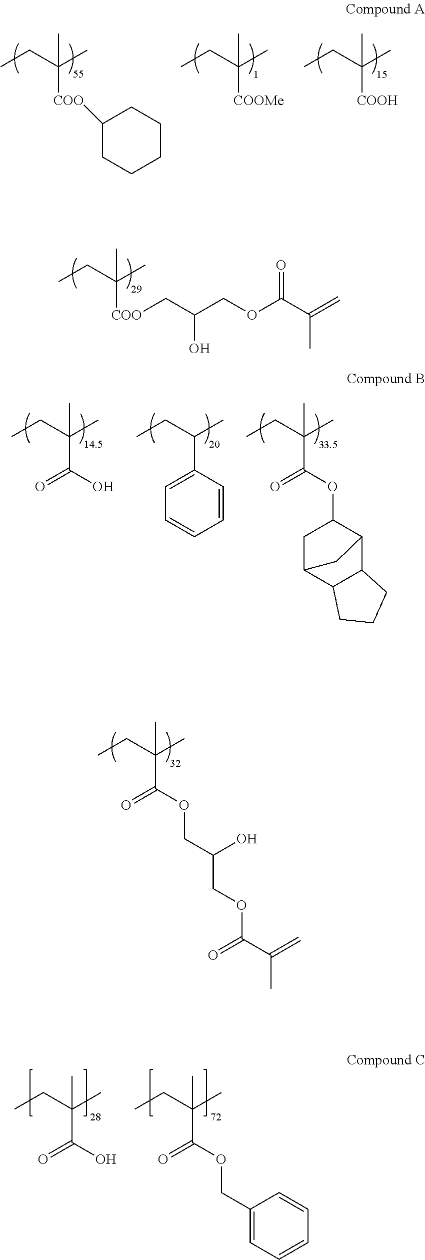

As the specific polymer A, the following compounds are also preferable. Content ratios (a to d) and weight-average molecular weights Mw of each of the constitutional units shown below can be appropriately changed according to the purpose.

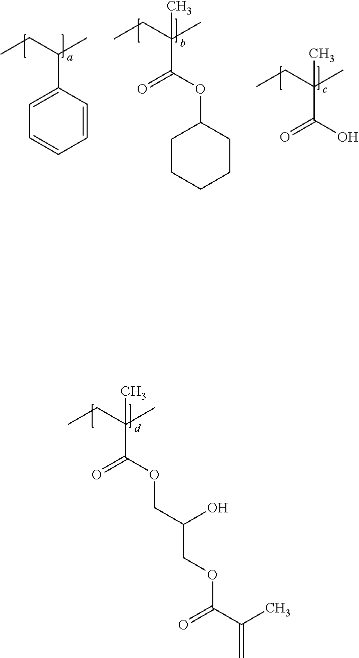

In the above-described compound, a is preferably 20% by mass to 60% by mass, b is preferably 10% by mass to 50% by mass, c is preferably 5.0% by mass to 25% by mass, and d is preferably 10% by mass to 50% by mass.

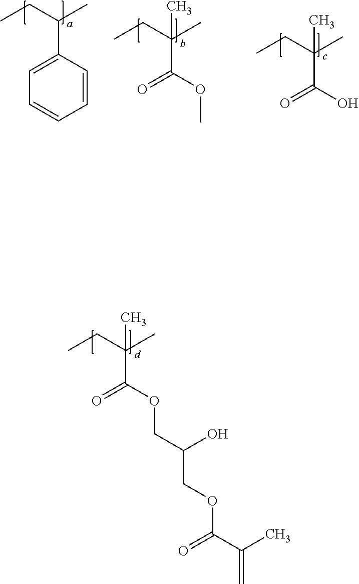

In the above-described compound, a is preferably 30% by mass to 65% by mass, b is preferably 1.0% by mass to 20% by mass, c is preferably 5.0% by mass to 25% by mass, and d is preferably 10% by mass to 50% by mass.

A weight-average molecular weight (Mw) of the specific polymer A is preferably 10,000 or more, more preferably 10,000 to 100,000, and still more preferably 15,000 to 50,000.

From the viewpoint of developability, a dispersity (weight-average molecular weight (Mw)/number-average molecular weight (Mn)) of the specific polymer A is preferably 1.0 to 2.0 and more preferably 1.0 to 1.5, and from the viewpoint of manufacturing suitability, the dispersity is preferably 1.8 to 2.8 and more preferably 2.0 to 2.5.

An acid value of the binder polymer is preferably 60 mgKOH/g to 200 mgKOH/g, more preferably 60 mgKOH/g to 150 mgKOH/g, and still more preferably 60 mgKOH/g to 110 mgKOH/g.

The acid value of the binder polymer is a value measured according to the method described in JIS K0070: 1992.

In a case where the photosensitive composition contains, as the binder polymer, a binder polymer (particularly, the specific polymer A) having an acid value of 60 mgKOH/g or more, in addition to the above-described advantages, a second resin layer described later contains a (meth)acrylic resin having an acid group, whereby interlaminar adhesion between a layer formed of the photosensitive composition and the second resin layer can be enhanced.

The photosensitive composition may contain, as the binder polymer, a polymer (hereinafter, also referred to as “polymer B”) including a constitutional unit having a carboxylic acid anhydride structure. In a case where the photosensitive composition contains the polymer B, the developability and the hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5-membered ring to 7-membered ring, more preferably a 5-membered ring or a 6-membered ring, and particularly preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

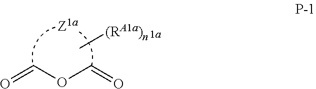

In Formula P-1, R^{A1a} represents a substituent, n^{1a} pieces of R^{A1a}s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and particularly preferably an alkylene group having 2 carbon atoms.

n^{1a} represents an integer of 0 or more. In a case where Zia represents an alkylene group having 2 to 4 carbon atoms, n^{1a} is preferably an integer of 0 to 4, more preferably an integer of 0 to 2, and particularly preferably 0.

In a case where n^{1a} represents an integer of 2 or more, a plurality of R^{A1a}'s may be the same or different. In addition, the plurality of R^{A1a}'s may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated aliphatic carboxylic acid anhydride, particularly preferably a constitutional unit derived from maleic acid anhydride or itaconic acid anhydride, and most preferably a constitutional unit derived from maleic acid anhydride.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

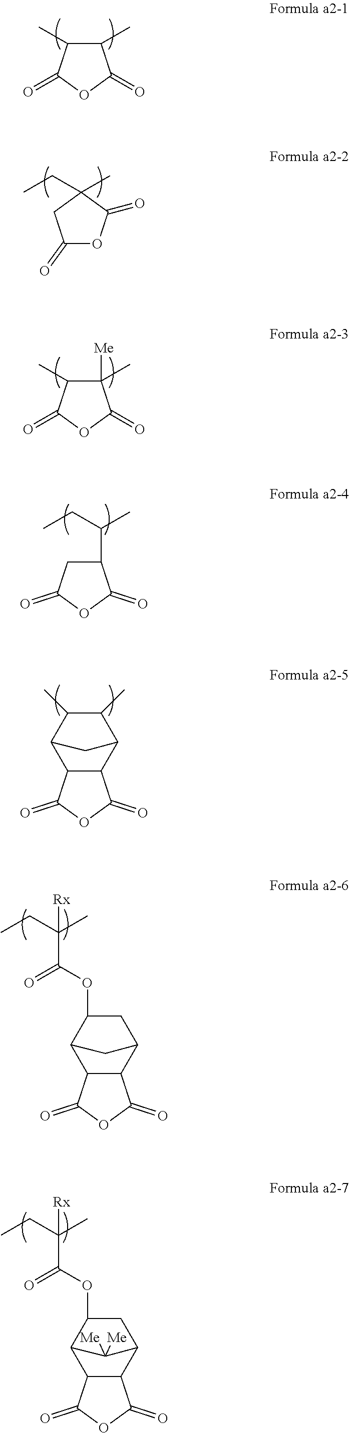

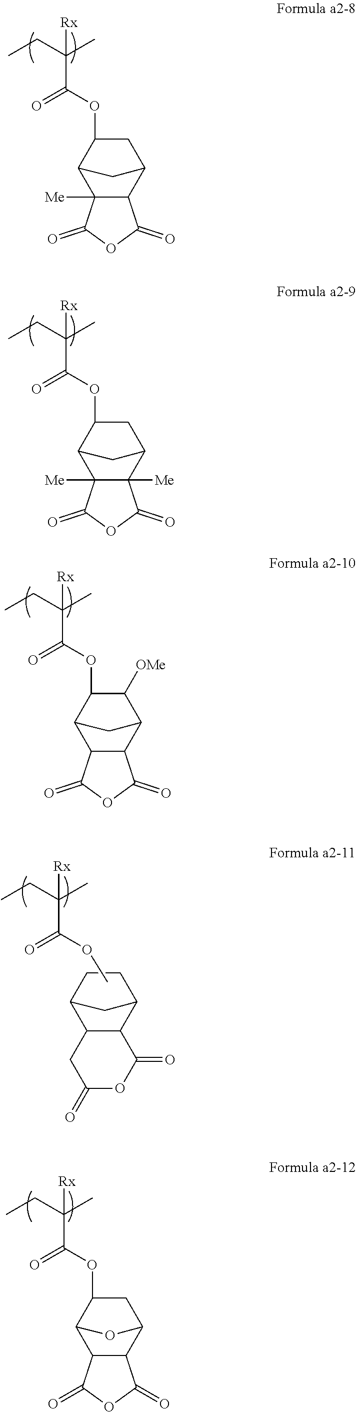

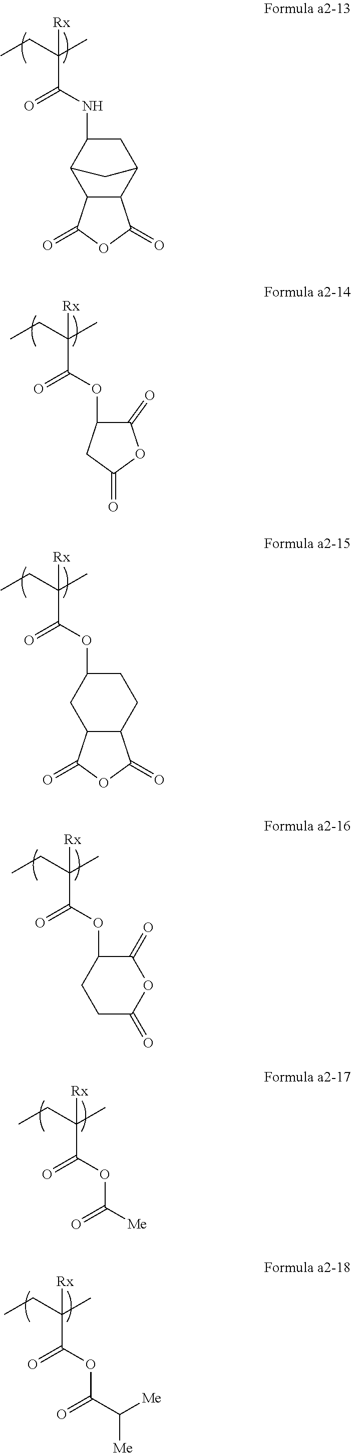

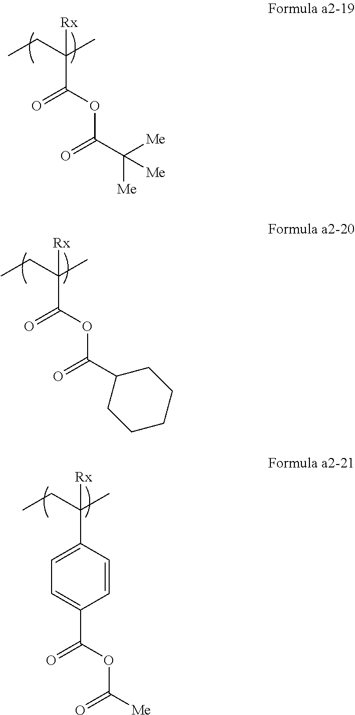

The polymer B may have only one kind of constitutional unit having a carboxylic acid anhydride structure, or two or more kinds thereof.

The total content of the constitutional unit having a carboxylic acid anhydride structure is preferably 0 mol % to 60 mol %, more preferably 5 mol % to 40 mol %, and particularly preferably 10 mol % to 35 mol % with respect to the total amount of the polymer B.

From the viewpoint of reliability, a ClogP value of the above-described binder polymer is preferably 2.00 or more, more preferably 2.20 or more, and particularly preferably 2.50 or more.

In addition, from the viewpoint of reliability, the ClogP value of the above-described binder polymer is preferably 5.00 or less, more preferably 4.50 or less, and particularly preferably 4.00 or less.

The ClogP value in the present disclosure is calculated using ChemDraw (registered trademark) Professional (ver. 16.0.1.4) manufactured by PerkinElmer Informatics.

Specifically, for example, the ClogP value is calculated by replacing the polymer with a monomer constituting the polymer. For example, in a case of polyacrylic acid, the calculation is performed by acrylic acid, and in a case of a polyacrylic acid-polymethacrylic acid copolymer (mass ratio of 50:50), ClogP values of acrylic acid and methacrylic acid are calculated, the values are multiplied by the mass ratio (0.5 each in this case), the total value thereof is defined as the ClogP value.

A weight-average molecular weight (Mw) of the binder polymer is not particularly limited, but is preferably more than 3,000, more preferably more than 3,000 and 60,000 or more, and still more preferably 5,000 to 50,000.

From the viewpoint of patterning properties and reliability, an amount of the residual monomer of each constitutional unit in the binder polymer is preferably 1,000 ppm by mass or less, more preferably 500 ppm by mass or less, and still more preferably 100 ppm by mass or less with respect to the binder polymer. The lower limit thereof is preferably 0.1 ppm by mass or more, and more preferably 1 ppm by mass or more.

It is preferable that the amount of the residual monomer of the monomer in a case of synthesizing the binder polymer by the polymer reaction is also within the above-described range. For example, in a case where glycidyl acrylate is reacted with a side chain having a carboxy group to synthesize the alkali-soluble resin, the content of glycidyl acrylate is preferably within the above-described range.

The amount of the residual monomer can be measured by a known method such as liquid chromatography and gas chromatography.

The photosensitive composition may contain only one kind of the binder polymer, or may include two or more kinds thereof.

From the viewpoint of strength of the cured film and handleability in the photosensitive transfer material, for example, a content of the binder polymer in the photosensitive composition is preferably 10% by mass to 90% by mass, more preferably 20% by mass to 80% by mass, and still more preferably 30% by mass to 70% by mass with respect to the total solid content of the photosensitive composition.

### <Polymerizable Compound>

From the viewpoint of photosensitivity and strength of the resin layer to be obtained after pattern formation, the photosensitive composition according to the present disclosure preferably contains a polymerizable compound.

Examples of the polymerizable compound include an ethylenically unsaturated compound, an epoxy compound, and an oxetane compound. Among these, from the viewpoint of photosensitivity and hardness of the resin layer to be obtained, an ethylenically unsaturated compound is preferable.

The polymerizable compound is a compound different from the specific blocked isocyanate compound.

The ethylenically unsaturated compound preferably includes a bi- or higher functional ethylenically unsaturated compound.

In the present disclosure, the “bi- or higher functional ethylenically unsaturated compound” means a compound having two or more ethylenically unsaturated groups in one molecule.

As the ethylenically unsaturated group, a (meth)acryloyl group is preferable.

As the ethylenically unsaturated compound, a (meth)acrylate compound is preferable.

From the viewpoint of hardness of the cured film after curing, for example, the ethylenically unsaturated compound particularly preferably includes a bifunctional ethylenic ally unsaturated compound (preferably, a bifunctional (meth)acrylate compound) and a tri- or higher functional ethylenically unsaturated compound (preferably, a tri- or higher functional (meth)acrylate compound). The upper limit of the number of functional groups of the tri- or higher functional ethylenically unsaturated compound is not particularly limited, but for example, it can be set to 15 or less.

The bifunctional ethylenically unsaturated compound is not particularly limited and can be appropriately selected from a known compound.

Examples of the bifunctional ethylenically unsaturated compound include tricyclodecane dimethanol di(meth)acrylate, 1,9-nonanediol di(meth)acrylate, and 1,6-hexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,10-decanediol diacrylate (product name: NK ESTER A-DOD-N, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), a mixture of dipentaerythritol hexaacrylate/dipentaerythritol pentaacrylate (KAYARAD DPHA76 manufactured by Nippon Kayaku Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 of Daicel-Allnex Ltd., or the like), and ethoxylated glycerin triacrylate (NK ESTER A-GLY-9E manufactured by Shin-Nakamura Chemical Co., Ltd., or the like).

As the ethylenically unsaturated compound, a urethane (meth)acrylate compound [preferably, a tri- or higher functional urethane (meth)acrylate compound] is also used.

Examples of the tri- or higher functional urethane (meth)acrylate compound include 8UX-015A (manufactured by Taisei Fine Chemical Co., Ltd.), NK ESTER UA-32P (manufactured by Shin-Nakamura Chemical Co., Ltd.), and NK ESTER UA-1100H (manufactured by Shin-Nakamura Chemical Co., Ltd.).

From the viewpoint of improving developability, the ethylenically unsaturated compound preferably includes an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 mgKOH/g to 120 mgKOH/g)), and a penta- to hexa-functional ethylenically unsaturated compound having an acid group [component obtained by introducing a carboxy group to dipentaerythritol penta- or hexa-acrylate (DPHA) skeleton (acid value: 25 mgKOH/g to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

As the bi- or higher functional ethylenically unsaturated compound having a carboxy group, ARONIX (registered trademark) TO-2349 (manufactured by Toagosei Co., Ltd.), ARONIX (registered trademark) M-520 (manufactured by Toagosei Co., Ltd.), ARONIX (registered trademark) M-510 (manufactured by Toagosei Co., Ltd.), or the like can be preferably used.

As the ethylenically unsaturated compound having an acid group, polymerizable compounds having an acid group, which are described in paragraphs 0025 to 0030 of JP2004-239942A, can be preferably used, and the contents described in this publication are incorporated in the present disclosure.

The photosensitive composition may contain one ethylenically unsaturated compound having an acid group alone, or two or more kinds thereof.

From the viewpoint of developability, and pressure-sensitive adhesiveness of an uncured film to be obtained, a content of the ethylenically unsaturated compound having an acid group is preferably 0.1% by mass to 30% by mass, more preferably 0.5% by mass to 20% by mass, still more preferably 1% by mass to 10% by mass, and particularly preferably 1% by mass to 5% by mass with respect to the total solid content of the photosensitive composition.

In addition, as the polymerizable compound contained in the photosensitive layer, the following aspects are also preferably mentioned.

From the viewpoint of film hardness, curing properties, and metal migration durability, the polymerizable compound contained in the photosensitive layer preferably includes a bifunctional (meth)acrylate compound, a pentafunctional (meth)acrylate compound, and a hexafunctional (meth)acrylate compound.

Furthermore, specifically, from the viewpoint of film hardness, curing properties, and metal migration durability, the polymerizable compound contained in the photosensitive layer preferably includes an alcanediol di(meth)acrylate compound, a pentafunctional (meth)acrylate compound; and a hexafunctional (meth)acrylate compound, and more preferably includes 1,9-nonanediol di(meth)acrylate or 1,10-decanediol di(meth)acrylate, dipentaerythritol hexa(meth)acrylate, and dipentaerythritol penta(meth)acrylate.

A molecular weight of the polymerizable compound is preferably 200 to 3,000, more preferably 250 to 2,600, still more preferably 280 to 2,200, and particularly preferably 300 to 2,200.

A proportion of the content of the polymerizable compound having a molecular weight of 300 or less in the polymerizable compounds contained in the photosensitive composition is preferably 30% by mass or less, more preferably 25% by mass or less, and still more preferably 20% by mass or less with respect to the content of all polymerizable compounds contained in the photosensitive composition.

The photosensitive composition may contain only one kind of the polymerizable compound or two or more kinds thereof.

A content of the polymerizable compound is preferably 1% by mass to 70% by mass, more preferably 10% by mass to 70% by mass, still more preferably 20% by mass to 60% by mass, and particularly preferably 20% by mass to 50% by mass with respect to the total solid content of the photosensitive composition.

In a case where the photosensitive layer contains a bifunctional ethylenically unsaturated compound and a tri- or higher functional ethylenically unsaturated compound, a content of the bifunctional ethylenically unsaturated compound is preferably 10% by mass to 90% by mass, more preferably 20% by mass to 85% by mass, and still more preferably 30% by mass to 80% by mass with respect to the total content of all ethylenically unsaturated compounds contained in the photosensitive composition.

In this case, a content of the trifunctional ethylenically unsaturated compound is preferably 10% by mass to 90% by mass, more preferably 15% by mass to 80% by mass, and still more preferably 20% by mass to 70% by mass with respect to the total content of all ethylenically unsaturated compounds contained in the photosensitive composition.

In this case, the content of the bi- or higher functional ethylenically unsaturated compound is preferably 40% by mass or more and less than 100% by mass, more preferably 40% by mass to 90% by mass, still more preferably 50% by mass to 80% by mass, and particularly preferably 50% by mass to 70% by mass with respect to the total content of the bifunctional ethylenically unsaturated compound and the tri- or higher functional ethylenically unsaturated compound.

In a case of containing the bi- or higher functional polymerizable compound, the photosensitive composition may further contain a monofunctional polymerizable compound.

In a case where the photosensitive composition contains the bi- or higher functional polymerizable compound, the bi- or higher functional polymerizable compound is preferably a main component of the polymerizable compound contained in the photosensitive composition.

In a case where the photosensitive composition contains the bi- or higher functional polymerizable compound, a content of the bi- or higher functional polymerizable compound is preferably 60% by mass to 100% by mass, more preferably 80% by mass to 100% by mass, and particularly preferably 90% by mass to 100% by mass with respect to the total content of all polymerizable compounds contained in the photosensitive composition.

In a case where the photosensitive composition contains the ethylenically unsaturated compound having an acid group (preferably, a bi- or higher functional ethylenically unsaturated compound containing a carboxy group or a carboxylic acid anhydride thereof), a content of the ethylenically unsaturated compound having an acid group is preferably 1% by mass to 50% by mass, more preferably 1% by mass to 20% by mass, and still more preferably 1% by mass to 10% by mass with respect to the total solid content of the photosensitive composition.

### <Polymerization Initiator>

The photosensitive composition can contain a polymerization initiator.

The polymerization initiator is not particularly limited, and a known photopolymerization initiator can be used.

The photopolymerization initiator may be a radical polymerization initiator or a cationic polymerization initiator, but a radical polymerization initiator is preferable.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-95716A and paragraphs 0064 to 0081 of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoropropoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(0-acetyloxime) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE 651, manufactured by BASF SE], an oxime ester-based product [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 3-cyclohexyl-1-[9-ethyl-6-(2-furanylcarbonyl)-9H-carbazol-3-yl]-1,2-propanedione-2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The photosensitive composition may contain only one kind of the polymerization initiator or two or more kinds thereof.

In a case where the photosensitive composition contains two or more kinds of the photopolymerization initiators, it is preferable that the photosensitive composition contains the oxime-based photopolymerization initiator and at least one selected from the group consisting of the α-aminoalkylphenone-based polymerization initiator and the α-hydroxyalkylphenone-based polymerization initiator.

A content of the polymerization initiator is not particularly limited, but is preferably 0.1% by mass or more, more preferably 0.5% by mass or more, and still more preferably 1.0% by mass or more with respect to the total solid content of the photosensitive composition.

In addition, the content of the polymerization initiator is preferably 10% by mass or less, and more preferably 5% by mass or less with respect to the total solid content of the photosensitive composition.

### <Halide Ion>

From the viewpoint of improving the reliability of the device and the like, it is preferable that the photosensitive composition does not contain a halide ion, or contains a halide ion and a content of the halide ion is preferably 5.0 ppm by mass or less with respect to the total solid content of the photosensitive composition, it is more preferable that the photosensitive composition does not contain a halide ion, or contains a halide ion and a content of the halide ion is more preferably 3.0 ppm by mass or less with respect to the total solid content of the photosensitive composition; and it still more preferable that the photosensitive composition does not contain a halide ion.

Examples of the halide ion include a fluoride ion, a chloride ion, a bromide ion, and an iodide ion.

In the present disclosure, the content of the halide ion contained in the photosensitive composition, the photosensitive layer described later, or the film or the cured film described later is measured by the following method.

The above-described photosensitive composition or the photosensitive layer described later is collected as a sample of approximately 100 mg, and approximately 100 mg of the collected sample is dissolved in 5 mL of propylene glycol monomethyl ether acetate. 5 mL of ultrapure water is added thereto, and the mixture is stirred for 2 hours. The mixture is left to stand for 12 hours or more, 1 mL of the aqueous layer is collected, and 9 mL of ultrapure water is added thereto to prepare a sample for measurement.

The prepared sample for measurement is subjected to ion chromatograph according to the measuring device and measuring conditions shown below, thereby measuring and calculating the content of the halide ion.
Ion chromatograph device: IC-2010 (manufactured by Tosoh Corporation)
Analytical column: TSKgel SuperIC-Anion HS
Guard column: TSKgel guard column SuperIC-A HS-Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (using suppressor)

Examples of a method of collecting the above-described photosensitive layer used for measuring the content of the halide ion include a method in which, in a case where a protective film is provided, the protective film is peeled off, the photosensitive layer on the photosensitive transfer material is laminated on glass, and the temporary support is peeled off to transfer the photosensitive layer and collect 100 mg of the photosensitive layer.

In addition, examples of a method of collecting the resin layer or the cured film described later include a method of scraping off 100 mg from the resin layer or the cured film and collecting the scraped-off resin layer or cured film.

### <Heterocyclic Compound>

The photosensitive composition may further contain a heterocyclic compound. The heterocyclic compound contributes to the improvement of adhesiveness to a layer containing a metal and corrosion inhibition properties of the metal.

A heterocyclic ring included in the heterocyclic compound may be a monocyclic or polycyclic heterocyclic ring.

Examples of a heteroatom included in the heterocyclic compound include an oxygen atom.

Examples of the heterocyclic ring of the heterocyclic compound include a furan ring, a benzofuran ring, an isobenzofuran ring, a tetrahydrofuran ring, a pyran ring, and a benzopyran ring.

The photosensitive composition may contain only one kind of the heterocyclic compound or two or more kinds thereof.

A content of the heterocyclic compound is preferably 0.01% by mass to 20% by mass, more preferably 0.1% by mass to 10% by mass, still more preferably 0.3% by mass to 8% by mass, and particularly preferably 0.5% by mass to 5% by mass with respect to the total solid content of the photosensitive composition. In a case where the content of the heterocyclic compound is within the above-described range, the adhesiveness to the layer containing a metal and the corrosion inhibition properties of the metal can be improved.

### <Thermal Crosslinking Compound>

From the viewpoint of hardness of the cured film to be obtained and pressure-sensitive adhesiveness of the uncured film to be obtained, it is preferable that the photosensitive composition contains a thermal crosslinking compound.

Examples of the thermal crosslinking compound include an epoxy compound, an oxetane compound, a methylol compound, and a blocked isocyanate compound other than the specific blocked isocyanate compound (hereinafter, also referred to as “other blocked isocyanate compound”).

In the present disclosure, in a case where the photosensitive layer contains only a radical polymerization initiator as the photopolymerization initiator, the above-described epoxy compound and the above-described oxetane compound are treated as the thermal crosslinking compound; and in a case of containing a cationic polymerization initiator, the above-described epoxy compound and the above-described oxetane compound are treated as the polymerizable compound.

As the other blocked isocyanate compounds, those disclosed in JP2016-181083A, JP2017-044965A, WO2018/105313A, and WO2020/059260A can be used.

As the other blocked isocyanate compounds, a commercially available product can be used.

Examples of the commercially available product of the other blocked isocyanate compounds include Karenz (registered trademark) AOI-BM, Karenz (registered trademark) MOI-BM, Karenz (registered trademark) MOI-BP, and the like (all manufactured by SHOWA DENKO K.K.), and block-type DURANATE series (for example, DURANATE (registered trademark) TPA-B80E, manufactured by Asahi Kasei Corporation).

The photosensitive composition may contain only one kind of the thermal crosslinking compound or two or more kinds thereof.

A content of the thermal crosslinking compound is preferably 1% by mass to 50% by mass and more preferably 5% by mass to 30% by mass with respect to the total solid content of the photosensitive composition.

### <Surfactant>

The photosensitive composition may contain a surfactant.

The surfactant is not particularly limited, and a known surfactant can be used.

Examples of the surfactant include surfactants described in paragraph 0017 of JP4502784B and paragraphs 0060 to 0071 of JP2009-237362A.

As the surfactant, a nonionic surfactant, a fluorine-based surfactant, or a silicon-based surfactant is preferable.

Examples of a commercially available product of the fluorine-based surfactant include MEGAFACE F-171, F-172, F-173, F-176, F-177, F-141, F-142, F-143, F-144, F-437, F-444, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, and 681 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can also be preferably used.

A block polymer can also be used as the fluorine-based surfactant. As the fluorine-based surfactant, a fluorine-containing polymer compound including a constitutional repeating unit derived from a (meth)acrylate compound having a fluorine atom and a constitutional repeating unit derived from a (meth)acrylate compound having 2 or more (preferably 5 or more) alkyleneoxy groups (preferably ethyleneoxy groups or propyleneoxy groups) can also be preferably used.

As the fluorine-based surfactant, a fluorine-containing polymer having an ethylenically unsaturated bond-containing group in the side chain can be used. Examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all manufactured by BASF SE), TETRONIC 304, 701, 704, 901, 904, and 150R1 (all manufactured by BASF SE), SOLSPERSE 20000 (manufactured by Lubrizol Corporation), NCW-101, NCW-1001, and NCW-1002 (all manufactured by FUJIFILM Wako Pure Chemical Corporation), PIONIN D-6112, D-6112-W, and D-6315 (all manufactured by Takemoto Oil&Fat Co., Ltd.), and OLFINE E1010 and SURFYNOL 104, 400, and 440 (all manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Chemical Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The photosensitive composition may contain only one kind of the surfactant or two or more kinds thereof.

A content of the surfactant is preferably 0.01% by mass to 3% by mass, more preferably 0.05% by mass to 1% by mass, and still more preferably 0.1% by mass to 0.8% by mass with respect to the total solid content of the photosensitive composition.

### <Hydrogen Donating Compound>

It is preferable that the photosensitive composition contains a hydrogen donating compound.

In the photosensitive composition, the hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society” Vol. 10, page 3173 (1972), JP1969-20189B (JP-S44-20189B), JP1976-82102A (JP-S51-82102A), JP1977-134692A (JP-S52-134692A), JP1984-138205A (JP-S59-138205A), JP1985-84305A (JP-S60-84305A), JP1987-18537A (JP-S62-18537A), JP1989-33104A (JP-S64-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-S48-42965B) (tributyl tin acetate and the like), a hydrogen donor described in JP1980-34414B (JP-S55-34414B), and a sulfur compound described in JP1994-308727A (JP-H6-308727A) (trithiane and the like).

The photosensitive composition may contain only one kind of the hydrogen donating compound or two or more kinds thereof.

For example, from the viewpoint of improving a curing rate by balancing the polymerization growth rate and chain transfer, a content of the hydrogen donating compound is preferably 0.01% by mass to 10% by mass, more preferably 0.03% by mass to 5% by mass, and still more preferably 0.05% by mass to 3% by mass with respect to the total solid content of the photosensitive composition.

### <Photoacid Generator>

The photosensitive composition preferably contains a photoacid generator.

The photoacid generator used in the present disclosure is a compound capable of generating an acid by irradiation with actinic rays such as ultraviolet rays, far ultraviolet rays, X-rays, and electron beams.

The photoacid generator used in the present disclosure is preferably a compound which is sensitive to actinic ray having a wavelength of 300 nm or more, preferably 300 nm to 450 nm, and generates an acid, and a chemical structure thereof is not limited. A photoacid generator which is not directly sensitive to actinic rays having a wavelength of 300 nm or more can also be preferably used in combination with a sensitizer as long as it is a compound which is sensitive to actinic rays having a wavelength of 300 nm or more and generates an acid by being used in combination with the sensitizer.

The photoacid generator used in the present disclosure is preferably a photoacid generator which generates an acid with a pKa of 4 or less, more preferably a photoacid generator which generates an acid with a pKa of 3 or less, and particularly preferably a photoacid generator which generates an acid with a pKa of 2 or less. The lower limit value of the pKa is not particularly limited, but is preferably −10.0 or more.

Examples of the photoacid generator include an ionic photoacid generator and a non-ionic photoacid generator.

Examples of the ionic photoacid generator include onium salt compounds such as diaryliodonium salts and triarylsulfonium salts, and quaternary ammonium salts. Among these, an onium salt compound is preferable, and triarylsulfonium salts or diaryliodonium salts are particularly preferable.

As the ionic photoacid generator, ionic photoacid generators described in paragraphs 0114 to 0133 of JP2014-85643A can also be preferably used.

Examples of the non-ionic photoacid generator include trichloromethyl-s-triazines, a diazomethane compound, an imide sulfonate compound, and an oxime sulfonate compound.

Among these, from the viewpoint of sensitivity, resolution, and adhesiveness, an oxime sulfonate compound is preferable as the photoacid generator. Specific examples of the trichloromethyl-s-triazines, the diazomethane compound, and the imide sulfonate compound include compounds described in paragraphs 0083 to 0088 of JP2011-221494A.

As the oxime sulfonate compound, compounds described in paragraphs 0084 to paragraph 0088 of WO2018/179640A can be suitably used.

The photosensitive composition may contain one photoacid generator alone, or may contain two or more photoacid generators.

From the viewpoint of sensitivity and resolution, a content of the photoacid generator in the photosensitive composition is preferably 0.1% by mass to 10% by mass, and more preferably 0.5% by mass to 5% by mass with respect to the total solid content of the photosensitive composition.

### <Solvent>

The photosensitive composition preferably contains a solvent.

As the solvent, a generally used solvent can be used without particular limitation.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

As the solvent, a mixed solvent of methyl ethyl ketone and propylene glycol monomethyl ether acetate or a mixed solvent of diethylene glycol ethyl methyl ether and propylene glycol monomethyl ether acetate is preferable.

As the solvent, solvents described in paragraphs 0054 and 0055 of US2005/282073A can also be used, and the contents of this specification are incorporated in the present disclosure.

In addition, as the solvent, an organic solvent (high-boiling-point solvent) having a boiling point of 180° C. to 250° C. can also be used, as necessary. In a case where the high-boiling-point solvent is contained, a content thereof is preferably 2% by mass to 20% by mass with respect to the total amount of the solvent.

In a case where the photosensitive composition contains a solvent, the photosensitive composition may contain only one kind of the solvent, or may contain two or more kinds thereof.

The total solid content of the photosensitive composition is preferably 5% by mass to 80% by mass, more preferably 5% by mass to 40% by mass, and particularly preferably 5% by mass to 30% by mass with respect to the total mass of the photosensitive composition.

### <Hygroscopic Material>

The photosensitive composition may contain a hygroscopic material.

The hygroscopic material is not particularly limited as long as it has an ability to absorb moisture, and examples thereof include cellulose nanofibers and inorganic fillers. Examples of the inorganic filler include a metal oxide and a metal hydroxide. Specific examples thereof include metal oxides such as calcium oxide, magnesium oxide, strontium oxide, aluminum oxide, barium oxide, calcined hydrotalcite, and calcined dolomite; and metal hydroxides such as calcium hydroxide, magnesium hydroxide, strontium hydroxide, aluminum hydroxide, barium hydroxide, zeolite, semi-calcined hydrotalcite, and uncalcined hydrotalcite. Among these, from the viewpoint of hygroscopicity, semi-calcined hydrotalcite or calcined hydrotalcite is preferable. From the viewpoint of transparency, hydrotalcite (that is, uncalcined hydrotalcite, semi-calcined hydrotalcite, or calcined hydrotalcite) is preferable.

From the viewpoint of transparency and hygroscopicity, the zeolite preferably has an average particle diameter of 300 nm or less, more preferably 200 nm or less, and particularly preferably 50 nm or less. By reducing the particle diameter, a surface area per unit volume increases, and thus the area of the voids can also be increased, whereby the moisture adsorption rate can be increased. The average particle diameter of the zeolite is determined as follows.

A specimen lightly pulverized with a mortar is ultrasonically dispersed in acetone, dropped onto a plastic support film, and naturally dried to be used as a specimen for microscopy, and a photograph is taken using a transmission electron microscope. For the primary particles in the photograph, an arithmetic mean of the longest diameter and the diameter in the perpendicular direction at the midpoint thereof is measured. An arithmetic average of the values measured for the 20 particles is obtained and defined as the average particle diameter.

Specific examples of the zeolite include Zeoal 4A-005 (average particle diameter: 50 nm, Nakamura Choukou Co., Ltd.), Zeoal 4A-030 (average particle diameter: 300 nm, Nakamura Choukou Co., Ltd.), Zeoal 5A (average particle diameter: 50 nm, Nakamura Choukou Co., Ltd.), Zeoal 3A (average particle diameter: 50 nm, Nakamura Choukou Co., Ltd.), ZSM-5 (average particle diameter: 100 nm, Nakamura Choukou Co., Ltd.), Zeolum F-9HA (Tosoh Corporation), Zeolum SA-500A (Tosoh Corporation), Zeolum SA-600A (Tosoh Corporation), Zeolum NSA-700 (Tosoh Corporation), and Zeolum HSZ-900 (Tosoh Corporation).

The hydrotalcite can be classified into an uncalcined hydrotalcite, a semi-calcined hydrotalcite, and a calcined hydrotalcite, and from the viewpoint of transparency and hygroscopicity of the photosensitive layer, a semi-calcined hydrotalcite or a calcined hydrotalcite or preferable. The uncalcined hydrotalcite is a metal hydroxide having a layered crystal structure, such as a natural hydrotalcite (Mg₆Al₂(OH)₁₆CO₃·4H₂O), and consists of, for example, a layer [Mg_{1-X}Al_{X}(OH)₂]^{X+} which serves as a basic skeleton and an interlayer [(CO₃)_{X/2}·mH₂O]^{X-}. The uncalcined hydrotalcite in the present invention is a concept including a hydrotalcite-like compound such as a synthetic hydrotalcite. Examples of the hydrotalcite-like compound include compounds represented by Formula (I) and Formula (II).

[M²⁺_{1-X}M^{3+x}(OH)₂]^{X+}·[(Aⁿ⁻)_{x/n}·mH₂O]^{X-} (I)

In the formula, M²⁺ represents a divalent metal ion such as Mg²⁺ and Zn²⁺, M³⁺ represents a trivalent metal ion such as Al³⁺ and Fe³⁺, An⁻ represents an n-valent anion such as CO₃²⁻, Cl⁻, and NO₃⁻, 0<x<1, 0≤m<1, and n is a positive number. In Formula (I), M²⁺ is preferably Mg²⁺, M³⁺ is preferably Al³⁺, and Aⁿ⁻ is preferably CO₃²⁻.

M²⁺ₓAl₂(OH)_{2x+6-nz}(Aⁿ⁻)_{z}·mH₂O (II)

In the formula, M²⁺ represents a divalent metal ion such as Mg²⁺ and Zn²⁺, Aⁿ⁻ represents an n-valent anion such as CO₃²⁻, Cl⁻, and NO₃⁻, x is a positive number of 2 or more, z is a positive number of 2 or less, m is a positive number, and n is a positive number. In Formula (II), M²⁺ is preferably Mg²⁺, and Aⁿ⁻ is preferably CO₃²⁻.

The semi-calcined hydrotalcite refers to a metal hydroxide having a layered crystal structure, which is obtained by calcining the uncalcined hydrotalcite, in which the amount of interlayer water is reduced or disappears.

On the other hand, the calcined hydrotalcite refers to a metal oxide having an amorphous structure, which is obtained by calcining the uncalcined hydrotalcite or the semi-calcined hydrotalcite, in which not only interlayer water but also hydroxyl groups have disappeared by condensation dehydration.

The uncalcined hydrotalcite, the semi-calcined hydrotalcite, and the calcined hydrotalcite can be distinguished by a saturated water absorption rate. The saturated water absorption rate of the semi-calcined hydrotalcite is 1% by mass or more and less than 20% by mass. On the other hand, the saturated water absorption rate of the uncalcined hydrotalcite is less than 1% by mass, and the saturated water absorption rate of the calcined hydrotalcite is 20% by mass or more.

The “saturated water absorption rate” refers to a mass increase rate with respect to an initial mass in a case where 1.5 g of the hygroscopic material is weighed on a balance, the initial mass is measured, and the hygroscopic material is allowed to stand for 200 hours in a small-scale environmental tester (SH-222 manufactured by ESPEC CORP.) set at 60° C. and 90% RH (relative humidity) under atmospheric pressure, and can be determined by the expression (i):

Saturated water absorption rate (% by mass)=100×(Mass after moisture absorption−Initial mass)/Initial mass (i).

The saturated water absorption rate of the hygroscopic material is preferably 4% by mass to 95% by mass, more preferably 10% by mass to 60% by mass, and still more preferably 20% by mass to 60% by mass.

The saturated water absorption rate of the semi-calcined hydrotalcite is preferably 3% by mass to 20% by mass and more preferably 10% by mass to 20% by mass. The saturated water absorption rate of the calcined hydrotalcite is preferably 20% by mass to 60% by mass and more preferably 40% by mass to 60% by mass.

Specific examples of the uncalcined hydrotalcite, the semi-calcined hydrotalcite, and the calcined hydrotalcite include DHT-4C (semi-calcined hydrotalcite, average particle diameter: 400 nm, manufactured by Kyowa Chemical Industry Co., Ltd.), DHT-4A-2 (semi-calcined hydrotalcite, average particle diameter: 400 nm, manufactured by Kyowa Chemical Industry Co., Ltd.), KW-2000 (calcined hydrotalcite, average particle diameter: 400 nm, manufactured by Kyowa Chemical Industry Co., Ltd.), KW-2200 (calcined hydrotalcite, average particle diameter: 400 nm, manufactured by Kyowa Chemical Industry Co., Ltd.), DHT-4A (uncalcined hydrotalcite, average particle diameter: 400 nm, manufactured by Kyowa Chemical Industry Co., Ltd.), ALMAKAISER 1 (uncalcined hydrotalcite, average particle diameter: 620 nm, manufactured by Kyowa Chemical Industry Co., Ltd.), MAGCELLER 1 (uncalcined hydrotalcite, average particle diameter: 470 nm, manufactured by Kyowa Chemical Industry Co., Ltd.), STABIACE HT-1 (uncalcined hydrotalcite, manufactured by Sakai Chemical Industry Co., Ltd.), STABIACE HT-7 (uncalcined hydrotalcite, manufactured by Sakai Chemical Industry Co., Ltd.), and STABIACE HT-P (uncalcined hydrotalcite, manufactured by Sakai Chemical Industry Co., Ltd.). The average particle diameter of the hydrotalcite is a value measured by the same method for the average particle diameter of the zeolite described above.

The cellulose nanofibers are nanocellulose extracted from a cellulose raw material (for example, wood). Examples of an extraction method of the cellulose nanofibers include a mechanical treatment (for example, a pulverization treatment with a beads mill) and a chemical treatment (for example, a (2,2,6,6-tetramethylpiperidine-1-oxyl) (TEMPO) catalytic oxidation treatment, a carboxymethylation treatment, a cationization treatment, and the like). As the cellulose nanofibers, cellulose nanofibers extracted by the mechanical treatment are preferable.

From the viewpoint of transparency, an average diameter (fiber diameter) of the cellulose nanofibers is preferably 2 nm to 20 nm, more preferably 2 nm to 10 nm, and still more preferably 2 nm to 7 nm.

From the viewpoint of transparency, an aspect ratio (average fiber length/average diameter) of the cellulose nanofibers is preferably 30 to 200, more preferably 100 to 200, and still more preferably 150 to 200.

Here, the “average fiber length” and the “average diameter” of the cellulose nanofibers are values measured based on a two-dimensional projection image (for example, an SEM photograph) of the cellulose nanofibers, respectively. Specifically, in the measurement of the “average fiber length” and the “average diameter” of the cellulose nanofibers, first, a fiber length or a diameter of each of 10 cellulose nanofibers randomly selected in the two-dimensional projection image is measured. Thereafter, an arithmetic average value of the measured fiber lengths or diameters of the cellulose nanofibers is calculated, and the calculated value is defined as the average fiber length or the average diameter.

Specific examples of the cellulose nanofibers include ELLEX-star (average diameter: 4 nm, aspect ratio: 187, manufactured by Daio Paper Corporation), AUROVISCO (average diameter: 5 nm, aspect ratio: 44, manufactured by Oji Holdings Corporation), RHEOCRYSTA (average diameter: 18 nm, aspect ratio: 138, manufactured by DKS Co., Ltd.), CELISH KYl00G (average diameter: 25 nm, aspect ratio: 144, manufactured by Daicel Fine Chemical Co., Ltd.), and cellenpia (average diameter: 3 nm, aspect ratio: 227, manufactured by Nippon Paper Industries Co., Ltd.).

A saturated water absorption rate of the cellulose nanofibers is preferably 60% by mass to 95% by mass and more preferably 75% by mass to 95% by mass.

As the hygroscopic material, a material which has been subjected to a surface treatment with a surface treatment agent can be used. As the surface treatment agent used for the surface treatment, for example, a higher fatty acid, alkylsilanes, a silane coupling agent, and the like can be used; and among these, a higher fatty acid or alkylsilanes are suitable. One type or two or more types of the surface treatment agents can be used.

Examples of the higher fatty acid include higher fatty acids having 18 or more carbon atoms, such as stearic acid, montanic acid, myristic acid, and palmitic acid; and among these, stearic acid is preferable. These may be used alone or in combination of two or more kinds thereof. Examples of the alkylsilanes include methyltrimethoxysilane, ethyltrimethoxysilane, hexyltrimethoxysilane, octyltrimethoxysilane, decyltrimethoxysilane, octadecyltrimethoxysilane, dimethyldimethoxysilane, octyltriethoxysilane, and n-octadecyldimethyl(3-(trimethoxysilyl)propyl)ammonium chloride. These may be used alone or in combination of two or more kinds thereof. Examples of the silane coupling agent include epoxy-based silane coupling agents such as 3-glycidyloxypropyltrimethoxysilane, 3-glycidyloxypropyltriethoxysilane, 3-glycidyloxypropyl(dimethoxy)methylsilane, and 2-(3,4-epoxycyclohexyl)ethyltrimethoxysilane; mercapto-based silane coupling agents such as 3-mercaptopropyltrimethoxysilane, 3-mercaptopropyltriethoxysilane, 3-mercaptopropylmethyldimethoxysilane, and 11-mercaptoundecyltrimethoxysilane; amino-based silane coupling agents such as 3-aminopropyltrimethoxysilane, 3-aminopropyltriethoxysilane, 3-aminopropyldimethoxymethylsilane, N-phenyl-3-aminopropyltrimethoxysilane, N-methylaminopropyltrimethoxysilane, N-(2-aminoethyl)-3-aminopropyltrimethoxysilane, and N-(2-aminoethyl)-3-aminopropyldimethoxymethylsilane; ureido-based silane coupling agents such as 3-ureidopropyltriethoxysilane; vinyl-based silane coupling agents such as vinyltrimethoxysilane, vinyltriethoxysilane, and vinylmethyldiethoxysilane; styryl-based silane coupling agents such as p-styryltrimethoxysilane; acrylate-based silane coupling agents such as 3-acryloxypropyltrimethoxysilane and 3-methacryloxypropyltrimethoxysilane; isocyanate-based silane coupling agents such as 3-isocyanatopropyltrimethoxysilane; sulfide-based silane coupling agents such as bis(triethoxysilylpropyl)disulfide and bis(triethoxysilylpropyl)tetrasulfide; and phenyltrimethoxysilane, methacryloxypropyltrimethoxysilane, imidazole silane, and triazine silane.

These may be used alone or in combination of two or more kinds thereof.

In a case where the photosensitive composition contains a hygroscopic m from the viewpoint of migration durability and transparency of the photosensitive layer, a content of the hygroscopic material in the photosensitive composition is preferably 0.01% by mass to 15% by mass, more preferably 0.01% by mass to 10% by mass, still more preferably 0.1% by mass to 10% by mass, and particularly preferably 0.1% by mass to 5% by mass with respect to the total solid content of the photosensitive composition.

In a case where the photosensitive composition contains an inorganic filler as the above-described hygroscopic material, the inorganic filler in the photosensitive composition may be present as an aggregate. In a case where the inorganic filler is added to the photosensitive composition, from the viewpoint of transparency and planar uniformity, it is preferable that a dispersion treatment is performed before or after the addition of the inorganic filler to adjust the aggregate size (dispersion particle diameter r (m)) of the inorganic filler in the photosensitive composition. In order to disperse the inorganic filler in the photosensitive composition, it is preferable to use a dispersion aid. Examples of the dispersion aid include known dispersion aids such as a surfactant and the above-described binder polymers.

The dispersion particle diameter r (m) of the inorganic filler can be controlled by changing the dispersion conditions known in the related art, such as the particle diameter of the inorganic filler, the adding amount of the inorganic filler, the kind of the solvent to be dispersed, the adding amount of the solvent to be dispersed, the dispersion method, the type of the disperser, the size of the disperser, the dispersion time, the energy per unit time given by the disperser to the dispersion liquid, the mixing method, the type of the binder, the adding amount of the binder, the adding order, and the amount of the dispersion liquid added.

The dispersion treatment is not particularly limited, and a conventional method can be used. Examples of the dispersion treatment method include a method using an attritor, a ball mill, a sand mill, or a dynomill as a media disperser. Examples of a media-less disperser include an ultrasonic type, a centrifugal type, and a high pressure type. In the present disclosure, the dispersion treatment is preferably a treatment using a dispersion method using an attritor, a ball mill, or ultrasonic waves.

From the viewpoint of transparency, it is preferable that the inorganic filler is dispersed by the above-described dispersion treatment method such that the dispersion particle diameter r (μm) contained in the photosensitive composition is 0.01 μm to 5.0 μm, more preferably 0.01 μm to 3.0 μm, still more preferably 0.01 μm to 2.0 μm, even more preferably 0.01 μm to 1.0 μm, even still more preferably 0.01 μm to 0.5 μm, further more preferably 0.01 am to 0.3 μm, and even further more preferably 0.01 μm to 0.2 μm.

The dispersion particle diameter r (m) of the inorganic filler is an average size of the inorganic filler contained in the photosensitive composition. The dispersion particle diameter of the inorganic filler contained in the photosensitive composition is one of physical property values which affect the transparency.

The dispersion particle diameter r is a value measured as follows.

A photosensitive layer is formed of the photosensitive composition. A method of forming the photosensitive layer will be described later.

The dispersion particle diameter is determined by the arithmetic average of particle diameters of 100 particles selected from a TEM image obtained by imaging the surface of the photosensitive layer and a cut surface obtained by cutting the photosensitive layer in a thickness direction with a transmission electron microscope (TEM). In a case where the inorganic filler is present as primary particles in the photosensitive layer in the TEM image, an arithmetic average of values measured for 100 particles is obtained, and the average primary particle diameter is defined as the dispersion particle diameter. In a case where the inorganic filler forms an aggregate, the particle diameter of the aggregate is defined as the dispersion particle diameter, and an arithmetic average value of values measured for 100 aggregated particles is defined as the dispersion particle diameter.

In a case where the photosensitive composition contains a hygroscopic material, from the viewpoint of reliability and transparency, a content of the hygroscopic material in the photosensitive composition is preferably 0.01% by mass to 30% by mass, more preferably 0.1% by mass to 25% by mass, and particularly preferably 0.1% by mass to 20% by mass with respect to the total solid content of the photosensitive composition.

### <<Other Components>>

The photosensitive composition may contain a component (so-called other components) other than the components described above.

Examples of the other components include particles (for example, metal oxide particles) and a colorant.

In addition, examples of the other components include a thermal polymerization inhibitor described in paragraph 0018 of JP4502784B and other additives described in paragraphs 0058 to 0071 of JP2000-310706A.

In addition, examples of the other additives include known additives such as a plasticizer, a sensitizer, an alkoxysilane compound, a thio compound, a basic compound, an ultraviolet absorber, and a rust inhibitor.

Examples of the plasticizer, the sensitizer, and the alkoxysilane compound include those described in paragraphs 0097 to 0119 of WO2018/179640A.

### —Particles—

The photosensitive composition may contain particles (for example, metal oxide particles; the same applies hereinafter) for the purpose of adjusting refractive index, light-transmitting property, and the like.

The metal of the metal oxide particles also includes semimetal such as B, Si, Ge, As, Sb, and Te.

From the viewpoint of transparency of the cured film, for example, an average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive composition contains particles, the photosensitive composition may contain only one kind of particles having different metal types, sizes, and the like, or may include two or more kinds thereof.

It is preferable that the photosensitive composition does not contain particles, or the content of the particles is more than 0% by mass to 35% by mass or less with respect to the total solid content of the photosensitive composition; it is more preferable that the photosensitive composition does not contain particles, or the content of the particles is more than 0% by mass to 10% by mass or less with respect to the total solid content of the photosensitive composition; it is still more preferable that the photosensitive composition does not contain particles, or the content of the particles is more than 0% by mass to 5% by mass or less with respect to the total solid content of the photosensitive composition; it is even more preferable that the photosensitive composition does not contain particles, or the content of the particles is more than 0% by mass to 1% by mass or less with respect to the total solid content of the photosensitive composition; and it is particularly preferably that the photosensitive composition does not contain particles.

### —Colorant—

The photosensitive composition may contain a trace amount of a colorant (pigment, dye, and the like), but for example, from the viewpoint of transparency, it is preferable that the photosensitive composition does not substantially contain the colorant.

A content of the colorant is preferably less than 1% by mass and more preferably less than 0.1% by mass with respect to the total solid content of the photosensitive composition.

### —Rust Inhibitor—

The photosensitive composition preferably contains a rust inhibitor. In a case where the photosensitive composition contains a rust inhibitor, rust (corrosion such as oxidation and sulfide) of a metal adjacent to the photosensitive composition can be suppressed.

Preferred examples of the rust inhibitor include a compound having an aromatic ring including a nitrogen atom in the molecule and having a molecular weight of 300 or less. Examples of the rust inhibitor include a compound having an imidazole skeleton, a compound having a tetrazole skeleton, a compound having a thiadiazole skeleton, and a compound having a triazole skeleton. Specific examples of the rust inhibitor include imidazole, benzimidazole, triazole, benzotriazole, tetrazole, 5-amino-1H-tetrazole, and mercaptothiadiazole.

A content of the rust inhibitor is preferably 0.1% by mass to 10% by mass, and more preferably 0.5% by mass to 5% by mass with respect to the total solid content of the photosensitive composition.

For example, from the viewpoint of coatability, a viscosity of the photosensitive composition according to the present disclosure at 25° C. is preferably 1 mPa·s to 50 mPa·s, more preferably 2 mPa·s to 40 mPa·s, and still more preferably 3 mPa·s to 30 mPa·s.

The viscosity is measured using a viscometer. As the viscometer, for example, a viscometer (product name: VISCOMETER TV-22) manufactured by Toki Sangyo Co., Ltd. can be suitably used. However, the viscometer is not limited thereto.

For example, from the viewpoint of coatability, a surface tension of the photosensitive composition according to the present disclosure at 25° C. is preferably 5 mN/m to 100 mN/m, more preferably 10 mN/m to 80 mN/m, and still more preferably 15 mN/m to 40 mN/m.

The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited thereto.

### (Cured Film)

The cured film according to the present disclosure is obtained by curing the photosensitive composition according to the present disclosure.

A manufacturing method of the cured film will be described in a manufacturing method of a laminate described later.

### (Photosensitive Transfer Material)

The photosensitive transfer material according to the present disclosure (hereinafter, also simply referred to as “photosensitive transfer material”) includes a temporary support and a photosensitive layer containing the photosensitive composition according to the present disclosure. Such a photosensitive transfer material can be suitably used for forming a cured film on a layer containing a metal.

Hereinafter, the photosensitive transfer material will be described in detail.

### <Temporary Support>

The photosensitive transfer material according to the present disclosure includes a temporary support.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxial stretching polyethylene terephthalate film), a cellulose triacetate film, a polystyrene film, a polyimide film, and a polycarbonate film.

Among these, as the temporary support, a biaxially stretching polyethylene terephthalate film is particularly preferable.

In addition, it is preferable that the film used as the temporary support does not have deformation such as wrinkles or scratches.

From the viewpoint that pattern exposure through the temporary support can be performed, the temporary support preferably has high transparency, and any transmittance at 313 nm, 365 nm, 405 nm, and 436 nm is preferably 60% or more, more preferably 70% or more, still more preferably 80% or more, and most preferably 90% or more. Examples of a preferred value of the transmittance include 87%, 92%, and 98%.

The transmittance is calculated as a proportion of the amount of light emitted from the temporary support to the amount of light incident at each wavelength (=Amount of emitted light/Amount of incidence ray x 100; %).

In addition, the total light transmittance of the temporary support is preferably 80% or more, and more preferably 85% or more. The total light transmittance is a value measured using a known spectrophotometer (for example, a haze meter NDH 2000, Nippon Denshoku Industries Co., Ltd.).

From the viewpoint of pattern formation during pattern exposure through the temporary support and transparency of the temporary support, it is preferable that the haze of the temporary support is small. Specifically, the haze value of the temporary support is preferably 2% or less, more preferably 0.5% or less, and particularly preferably 0.1% or less.

From the viewpoint of pattern formation during pattern exposure through the temporary support and transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

From the viewpoint of imparting handleability, a layer (lubricant layer) containing fine particles may be provided on a surface of the temporary support. The lubricant layer may be provided on one surface of the temporary support or on both surfaces thereof. A diameter of the particles contained in the lubricant layer can be, for example, 0.05 μm to 0.8 μm. In addition, a layer thickness of the lubricant layer can be, for example, 0.05 μm to 1.0 μm.

A thickness of the temporary support is not particularly limited, but is preferably 5 μm to 200 μm. In addition, from the viewpoint of ease of handling and general-purpose properties, the thickness thereof is more preferably 10 μm to 150 μm and still more preferably 10 to 50 μm.

Preferred aspects of the temporary support are described in, for example, paragraphs 0017 and 0018 of JP2014-85643A, paragraphs 0019 to 0026 of JP2016-27363A, paragraphs 0041 to 0057 of WO2012/081680A, and paragraphs 0029 to 0040 of WO2018/179370A, and the contents of these publications are incorporated in the present specification.

Examples of the temporary support include LUMIRROR (registered trademark) 16FB40 manufactured by Toray Industries, Inc., LUMIRROR (registered trademark) 16QS62 (16KS40) manufactured by Toray Industries, Inc.; and COSMOSHINE (registered trademark) A4100, COSMOSHINE (registered trademark) A4160, COSMOSHINE (registered trademark) A4300, COSMOSHINE (registered trademark) A4360, and COSMOSHINE (registered trademark) A8300 (all of which are manufactured by TOYOBO Co., Ltd.).

In addition, particularly preferred examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

The temporary support may be a recycled product. Examples of the recycled product include films obtained by washing used films and the like into chips and using the chips as a material. Specific examples of the recycled product include Ecouse series of Toray Industries, Inc.

### <Photosensitive Layer>

The photosensitive transfer material according to the present disclosure includes a photosensitive layer containing the photosensitive composition according to the present disclosure on the above-described temporary support.

The photosensitive layer may be a negative tone photosensitive layer or a positive tone photosensitive layer, but is preferably a negative tone photosensitive layer.

A thickness of the photosensitive layer is not particularly limited, but from the viewpoint of manufacturing suitability, reducing the thickness of the entire photosensitive transfer material, improvement of the transmittance of the photosensitive layer or a cured film to be obtained, and suppression of yellowing of the photosensitive layer or a cured film to be obtained, the thickness of the photosensitive layer is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

The thickness of each layer such as the photosensitive layer is obtained as an average value of 5 random points measured by cross-sectional observation with a scanning electron microscope (SEM).

A refractive index of the photosensitive layer is not particularly limited, but is preferably 1.47 to 1.56, more preferably 1.50 to 1.53, still more preferably 1.50 to 1.52, and particularly preferably 1.51 to 1.52.

It is not necessary that the solvent used in forming the photosensitive layer is completely removed. For example, a content of the solvent in the photosensitive layer is preferably 5% by mass or less, more preferably 1% by mass or less, and particularly preferably 0.5% by mass or less with respect to the total mass of the photosensitive layer. In addition, from the viewpoint of imparting developability and the like, the content thereof is preferably 0.05% by mass or more.

### —Color of Photosensitive Layer—

The above-described photosensitive layer is preferably achromatic. In the L*a*b* color system, the a* value of the above-described photosensitive layer is preferably −1.0 to 1.0, and the b* value is preferably −1.0 to 1.0.

### —Refractive Index of Photosensitive Layer—

A refractive index of the photosensitive layer is preferably 1.41 to 1.59 and more preferably 1.47 to 1.56

### —Visible Light Transmittance of Photosensitive Layer—

A visible light transmittance of the photosensitive layer at a film thickness of approximately 1.0 μm is preferably 80% or more, more preferably 90% or more, and particularly preferably 95% or more.

As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above.

Examples of a preferred value of the transmittance include 87%, 92%, and 98%.

The same applies to a transmittance of the cured film of the photosensitive layer at a film thickness of approximately 1.0 μm.

### —Moisture Permeability of Photosensitive Layer—

From the viewpoint of device reliability, a moisture permeability of a pattern obtained by curing the photosensitive layer (cured film of the photosensitive layer) at a film thickness of m is preferably 500 g/(m²·24 hr) or less, more preferably 300 g/(m²·24 hr) or less, and still more preferably 100 g/(m²·24 hr) or less.

The moisture permeability is measured with a cured film obtained by curing the photosensitive layer by exposing the photosensitive layer with i-rays at an exposure amount of 300 mJ/cm², and then performing post-baking at 145° C. for 30 minutes.

The moisture permeability is measured according to a cup method of JIS Z0208. It is preferable that the above-described moisture permeability is as above under any test conditions of temperature 40° C. and humidity 90%, temperature 65° C. and humidity 90%, or temperature 80° C. and humidity 95%.

Examples of a specific preferred numerical value include 80 g/(m²·24 hr), 150 g/(m²·24 hr), and 220 g/(m²·24 hr).

### —Dissolution Rate of Photosensitive Layer—

From the viewpoint of suppressing residue during development, a dissolution rate of the photosensitive layer in an aqueous solution of 1.0% sodium carbonate is preferably 0.01 m/sec or more, more preferably 0.10 μm/sec or more, and still more preferably 0.20 μm/sec or more. From the viewpoint of edge shape of the pattern, it is preferable to be 5.0 μm/sec or less, more preferable to be 4.0 μm/sec or less, and still more preferable to be 3.0 μm/sec or less.

Examples of a specific preferred numerical value include 1.8 μm/sec, 1.0 μm/sec, and 0.7 μm/sec.

The dissolution rate of the photosensitive layer in an aqueous solution of 1.0% by mass sodium carbonate per unit time is measured as follows.

A photosensitive layer (within a film thickness of 1.0 to 10 m) formed on a glass substrate, from which the solvent has been sufficiently removed, is subjected to a shower development with an aqueous solution of 1.0% by mass sodium carbonate at 25° C. until the photosensitive layer is dissolved completely (here, the maximum time is 2 minutes). The dissolution rate of the photosensitive layer is obtained by dividing the film thickness of the photosensitive layer by the time required for the photosensitive layer to dissolve completely. In a case where the photosensitive layer is not dissolved completely in 2 minutes, the dissolution rate of the photosensitive layer is calculated in the same manner as above, from the amount of change in film thickness up to 2 minutes.

A dissolution rate of the cured film (within a film thickness of 1.0 μm to 10 m) of the photosensitive layer in an aqueous solution of 1.0% sodium carbonate is preferably 3.0 μm/sec or less, more preferably 2.0 μm/sec or less, still more preferably 1.0 μm/sec or less, and most preferably 0.2 μm/sec or less. The cured film of the photosensitive layer is a film obtained by exposing the photosensitive layer with i-rays at an exposure amount of 300 mJ/cm².

Examples of a specific preferred numerical value include 0.8 μm/sec, 0.2 μm/sec, and 0.001 μm/sec.

For development, a shower nozzle of 1/4 MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

### —Swelling Ratio of Photosensitive Layer—

From the viewpoint of improving pattern formability, a swelling ratio of the photosensitive layer after exposure with respect to a 1.0% by mass sodium carbonate aqueous solution is preferably 100% or less, more preferably 50% or less, and still more preferably 30% or less.

The swelling ratio of the photosensitive layer after exposure with respect to a 1.0% by mass sodium carbonate aqueous solution is measured as follows.

A photosensitive layer (within a film thickness of 1.0 to 10 m) formed on a glass substrate, from which the solvent has been sufficiently removed, is exposed at an exposure amount of 500 mJ/cm² (i-ray measurement) with an ultra-high pressure mercury lamp. The glass substrate is immersed in an aqueous solution of 1.0% by mass sodium carbonate at 25° C., and the film thickness is measured after 30 seconds. Next, an increased proportion of the film thickness after immersion to the film thickness before immersion is calculated.

Examples of a specific preferred numerical value include 4%, 13%, and 25%.

### —Foreign Substance in Photosensitive Layer—

From the viewpoint of pattern formability, the number of foreign substances having a diameter of 1.0 μm or more in the photosensitive layer is preferably 10 pieces/mm² or less, and more preferably 5 pieces/mm² or less.

The number of foreign substances is measured as follows.

Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances.

Examples of a specific preferred numerical value include 0 pieces/mm², 1 pieces/mm², 4 pieces/mm², and 8 pieces/mm².

### —Haze of Dissolved Substance in Photosensitive Layer—

From the viewpoint of suppressing generation of aggregates during development, a haze of a solution obtained by dissolving 1.0 cm³ of the photosensitive layer in 1.0 liter of an aqueous solution of 1.0% by mass sodium carbonate at 30° C. is preferably 60% or less, more preferably 30% or less, still more preferably 10% or less, and particularly preferably 1% or less.

The haze is measured as follows.

First, a 1.0% by mass sodium carbonate aqueous solution is prepared, and a liquid temperature is adjusted to 30° C. 1.0 cm³ of the photosensitive layer is added to 1.0 μL of the sodium carbonate aqueous solution. The solution is stirred at 30° C. for 4 hours, being careful not to mix air bubbles. After stirring, the haze of the solution in which the photosensitive layer is dissolved is measured. The haze is measured using a haze meter (for example, product name “NDH4000”, manufactured by Nippon Denshoku Industries Co., Ltd.), a liquid measuring unit, and a liquid measuring cell having an optical path length of 20 mm.

Examples of a specific preferred numerical value include 0.4%, 1.0%, 9%, and 24%.

### <Second Resin Layer>

The photosensitive transfer material according to the present disclosure may further include a second resin layer between the temporary support and the photosensitive layer.

Examples of the second resin layer include a thermoplastic resin layer described below, and an interlayer.

In addition, as the second resin layer, the photosensitive transfer material according to the present disclosure may include a thermoplastic resin layer or an interlayer between the temporary support and the photosensitive layer, or may include both the thermoplastic resin layer and the interlayer between the temporary support and the photosensitive layer.

### —Thermoplastic Resin Layer—

The photosensitive transfer material according to the present disclosure may further include a thermoplastic resin layer between the temporary support and the photosensitive layer.

As the photosensitive transfer material further includes a thermoplastic resin layer, in a case where the photosensitive transfer material is transferred to a substrate to form a film, air bubbles due to lamination are less likely to be generated. In a case where the film is used in an image display apparatus, image unevenness and the like are hardly generated and excellent display properties are obtained.

The thermoplastic resin layer preferably has alkali solubility.

The thermoplastic resin layer functions as a cushion material which absorbs ruggedness of the surface of the substrate during transfer.

The ruggedness of the surface of the substrate includes an image, an electrode, a wiring, and the like, which are formed in advance.

The thermoplastic resin layer preferably has properties capable of being deformed in accordance with ruggedness.

The thermoplastic resin layer preferably includes an organic polymer substance described in JP1993-72724A (JP-H5-72724A), and more preferably includes an organic polymer substance having a softening point approximately 80° C. or lower by a Vicat method (specifically, polymer softening point measurement method using an American Society for Testing and Materials ASTM D1235).

A thickness of the thermoplastic resin layer is preferably 3 μm to 30 μm, more preferably 4 μm to 25 μm, and still more preferably 5 μm to 20 μm.

In a case where the thickness of the thermoplastic resin layer is 3 μm or more, followability with respect to the ruggedness of the surface of the substrate is improved, and the ruggedness of the surface of the substrate can be effectively absorbed.

In a case where the thickness of the thermoplastic resin layer is 30 μm or less, since the manufacturing suitability is more improved, for example, burden of the drying (so-called drying for removing the solvent) in a case of applying and forming the thermoplastic resin layer on the temporary support is further reduced, and the development time of the thermoplastic resin layer after the transfer is further shortened.

The thickness of the thermoplastic resin layer is obtained as an average value of 5 random points measured by cross-sectional observation with a scanning electron microscope (SEM).

The thermoplastic resin layer can be formed by applying and, as necessary, drying a composition for forming a thermoplastic resin layer including a solvent and a thermoplastic organic polymer on the temporary support.

Specific examples of coating and drying methods in the forming method of the thermoplastic resin layer are the same as the specific examples of coating and drying in the forming method of the photosensitive layer, respectively.

The solvent is not particularly limited as long as the solvent dissolves the polymer component forming the thermoplastic resin layer.

Examples of the solvent include organic solvents (for example, methyl ethyl ketone, cyclohexanone, propylene glycol monomethyl ether acetate, n-propanol, and 2-propanol).

A viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive layer measured at 100° C.

### —Interlayer—

The photosensitive transfer material according to the present disclosure may further include an interlayer between the temporary support and the photosensitive layer.

In a case where the photosensitive transfer material according to the present disclosure includes the thermoplastic resin layer, the interlayer is preferably disposed between the thermoplastic resin layer and the photosensitive layer.

Examples of a component contained in the interlayer include at least one polymer selected from the group consisting of polyvinyl alcohol, polyvinylpyrrolidone, and cellulose.

In addition, as the interlayer, a component described in JP1993-72724A (JP-H5-72724A) as “separation layer” can also be used.

In a case of manufacturing the photosensitive transfer material including, on the temporary support, the thermoplastic resin layer, the interlayer, and the photosensitive layer in this order, for example, the interlayer can be formed by applying and, as necessary, drying a composition for forming an interlayer, containing a solvent which does not dissolve the thermoplastic resin layer, and the above-described polymer as the component of the interlayer.

Specifically, first, the composition for forming a thermoplastic resin layer is applied and dried onto the temporary support to form the thermoplastic resin layer. Next, the composition for forming an interlayer is applied onto the formed thermoplastic resin layer and dried as necessary to form the interlayer. Next, the photosensitive composition containing an organic solvent is applied onto the formed interlayer and dried to form a photosensitive layer. The organic solvent contained in the photosensitive composition is preferably an organic solvent which does not dissolve the interlayer.

Specific examples of coating and drying methods in the forming method of the interlayer are the same as the specific examples of coating and drying in the forming method of the photosensitive layer, respectively.

### <Refractive Index-Adjusting Layer>

The photosensitive transfer material according to the present disclosure may further include a refractive index-adjusting layer between the photosensitive layer and a protective film.

The refractive index-adjusting layer is not limited, and a known refractive index-adjusting layer can be adopted. Examples of a material contained in the refractive index-adjusting layer include a binder and particles.

The binder is not limited, and a known binder can be applied. Examples of the binder include the above-described binder polymer.

The particles are not limited, and known particles can be applied. Examples of the particles include zirconium oxide particles (ZrO₂ particles), niobium oxide particles (Nb₂O5 particles), titanium oxide particles (TiO₂ particles), and silicon dioxide particles (SiO₂ particles).

In addition, the refractive index-adjusting layer preferably contains a metal oxidation inhibitor. In a case where the refractive index-adjusting layer contains a metal oxidation inhibitor, oxidation of metal in contact with the refractive index-adjusting layer can be suppressed.

Preferred examples of the metal oxidation inhibitor include a compound having an aromatic ring including a nitrogen atom in the molecule. Specific examples of the metal oxidation inhibitor include imidazole, benzimidazole, tetrazole, mercaptothiadiazole, and benzotriazole.

A refractive index of the refractive index-adjusting layer is preferably 1.50 or more, more preferably 1.55 or more, and particularly preferably 1.60 or more.

In addition, the upper limit of the refractive index of the refractive index-adjusting layer is not particularly limited, but is preferably 2.10 or less and more preferably 1.85 or less.

A thickness of the refractive index-adjusting layer is preferably 500 nm or less, more preferably 110 nm or less, and particularly preferably 100 nm or less.

In addition, the thickness of the refractive index-adjusting layer is preferably 20 nm or more and more preferably 50 nm or more.

The thickness of the refractive index-adjusting layer is obtained as an average value of 5 random points measured by cross-sectional observation with a scanning electron microscope (SEM).

A method for forming the refractive index-adjusting layer is not limited, and a known method can be adopted. Examples of the method for forming the refractive index-adjusting layer include a method using a composition for a refractive index-adjusting layer. For example, the composition for a refractive index-adjusting layer is applied on an object to be coated, and the composition is dried as necessary to form a refractive index-adjusting layer.

Examples of a method for producing the composition for the refractive index-adjusting layer include a method of mixing the above-described components and a solvent. The mixing method is not limited, and a known method can be applied.

The solvent is not limited, and a known solvent can be applied. Examples of the solvent include water, and organic solvents described in the above section of “method for forming the photosensitive layer”.

As the coating method and drying method, the coating method and drying method described in the above section of “Method for Forming Photosensitive Layer” can be adopted, respectively.

### <Antistatic Layer>

The photosensitive transfer material according to the present disclosure may further include an antistatic layer between the photosensitive layer and a protective film or between the photosensitive layer and the temporary support. In a case where the photosensitive transfer material according to the present disclosure includes an antistatic layer, it is possible to suppress generation of static electricity in a case of peeling off a film or the like, disposed on the antistatic layer, and it is also possible to suppress generation of static electricity due to rubbing with equipment or another film. As a result, for example, it is possible to suppress occurrence of a malfunction in the electronic apparatus.

From the viewpoint of suppressing the generation of static electricity, the antistatic layer is preferably disposed between the temporary support and the photosensitive layer.

The antistatic layer is a layer having antistatic properties, and contains at least an antistatic agent. The antistatic agent is not limited, and a known antistatic agent can be used.

The antistatic layer preferably contains, as the antistatic agent, at least one compound selected from the group consisting of an ionic liquid, an ionic conductive polymer, an ionic conductive filler, and an electrically conductive polymer (also referred to as “conductive polymer”).

The ionic liquid is preferably an ionic liquid composed of a fluoroorganic anion and an onium cation.

Examples of the ionic conductive polymer include an ionic conductive polymer obtained by polymerizing or copolymerizing a monomer having a quaternary ammonium base. As a counter ion of the quaternary ammonium base, a non-halogen ion is preferable. Examples of the non-halogen ion include a sulfonate anion and a carboxylate anion.

Examples of the ionic conductive filler include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, indium oxide/tin oxide (ITO), and antimony oxide/tin oxide (ATO).

Examples of the conductive polymer include polythiophene, polyaniline, polypyrrole, polyethyleneimine, and arylamine-based polymers. Specific examples of the conductive polymer include (3,4-ethylenedioxythiophene)-poly(styrene sulfonic acid).

Among the above, the antistatic agent is preferably polythiophene. As the polythiophene, a polymer compound containing poly(3,4-ethylenedioxythiophene) (PEDOT) is preferable, and a conductive polymer consisting of poly(3,4-ethylenedioxythiophene) and polystyrene sulfonic acid (hereinafter, abbreviated as “PEDOT/PSS”) is particularly preferable.

The antistatic layer may contain only one kind of the antistatic agent, or may contain two or more kinds of the antistatic agents.

From the viewpoint of antistatic properties, a content of the antistatic agent is preferably 0.1% by mass to 100% by mass with respect to the total mass of the layer including the antistatic layer. In a case where the antistatic agent is a solvent-dispersed antistatic agent, the content of the antistatic agent is more preferably 1% by mass to 10% by mass, and particularly preferably 3% by mass to 10% by mass with respect to the total mass of the antistatic layer. In a case where the antistatic agent is not a solvent-dispersed antistatic agent, the content of the antistatic agent is more preferably 60% by mass to 100% by mass, and particularly preferably 70% by mass to 100% by mass with respect to the total mass of the antistatic layer.

The antistatic layer may further contain a component other than the antistatic agent as necessary. Examples of the component other than the antistatic agent include a binder polymer (for example, polyvinylpyrrolidone, polyvinyl alcohol, and an acrylic resin), a curing component (for example, a polymerizable compound and a photopolymerization initiator), and a surfactant.

An average thickness of the antistatic layer is preferably 1 μm or less, more preferably 0.6 μm or less, still more preferably 0.4 μm or less, and particularly preferably 0.2 μm or less. In a case where the average thickness of the antistatic layer is 1 μm or less, the haze can be reduced. The lower limit of the thickness of the antistatic layer is not limited. From the viewpoint of manufacturing suitability, the average thickness of the antistatic layer is preferably 0.01 μm or more. The average thickness of the antistatic layer is an arithmetic average of thicknesses at five positions measured by cross-sectional observation using a scanning electron microscope (SEM).

Examples of the method for forming the antistatic layer include a method using a composition for the antistatic layer. For example, a method of applying the composition for the antistatic layer onto an object to be coated (for example, the temporary support or the photosensitive layer) can be used. Examples of the coating method include a printing method, a spray method, a roll coating method, a bar coating method, a curtain coating method, a spin coating method, and a die coating method (that is, a slit coating method). Among the above, the coating method is preferably a die coating method.

In the method for forming the antistatic layer, the photosensitive composition applied onto the object to be coated may be dried as necessary. Examples of the drying method include natural drying, heating drying, and drying under reduced pressure.

### <Protective Film>

The photosensitive transfer material according to the present disclosure may further include a protective film on a side opposite to a side on which the temporary support is provided, as viewed from the photosensitive layer.

The protective film is preferably an outermost layer of the surface of the photosensitive transfer material according to the present disclosure opposite to the side on which the temporary support is provided.

Examples of the protective film include a polyethylene terephthalate film, a polypropylene film, a polystyrene film, and a polycarbonate film.

As the protective film, for example, films described in paragraphs 0083 to 0087 and 0093 of JP2006-259138A may be used.

A thickness of the protective film is preferably 1 μm to 100 μm, more preferably 5 μm to 50 μm, still more preferably 5 μm to 40 μm, and particularly preferably 15 μm to 30 km. From the viewpoint of excellent mechanical hardness, the thickness of the protective film is preferably 1 μm or more; and from the viewpoint of relatively low cost, the thickness of the protective film is preferably 100 μm or less.

The protective film is also available as ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc.

In order to make it easier to peel off the protective film from the photosensitive layer or the refractive index-adjusting layer, it is preferable that an adhesive force between the protective film and the photosensitive layer or the refractive index-adjusting layer is smaller than an adhesive force between the temporary support and the photosensitive layer.

In addition, the protective film preferably has 5 pieces/m² or less of the number of fisheyes with a diameter of 80 μm or more in the protective film. The “fisheye” means that, in a case where a material is hot-melted, kneaded, extruded, biaxially stretched, cast or the like to manufacture a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles contained in the protective film being transferred to a metal of the photosensitive layer, the conductive layer, or the like.

In the protective film, from the viewpoint of imparting take-up property, an arithmetic average roughness Ra on a surface opposite to a surface in contact with the photosensitive layer or the refractive index-adjusting layer is preferably 0.01 μm or more, more preferably 0.02 μm or more, and still more preferably 0.03 μm or more. On the other hand, it is preferable to be less than 0.50 μm, it is more preferable to be 0.40 μm or less, and it is still more preferable to be 0.30 μm or less.

In the protective film, from the viewpoint of suppressing defects during transfer, the surface roughness Ra on the surface in contact with the photosensitive layer or the refractive index-adjusting layer is preferably 0.01 μm or more, more preferably 0.02 μm or more, and still more preferably 0.03 μm or more. On the other hand, it is preferable to be less than 0.50 μm, it is more preferable to be 0.40 μm or less, and it is still more preferable to be 0.30 μm or less.

### —Impurities and the Like—

It is preferable that impurities contained in each of the photosensitive layer, the second resin layer, the refractive index-adjusting layer, and the antistatic layer are small.

Examples of the impurities include sodium, potassium, magnesium, calcium, iron, manganese, copper, aluminum, titanium, chromium, cobalt, nickel, zinc, tin, and ions of these.

A content of the impurities in each layer is preferably 80 ppm or less, more preferably 10 ppm or less, and still more preferably 2 ppm or less on a mass basis. The lower limit thereof is not particularly limited, but the content of the impurities in each layer can be 1 ppb or more, or 0.1 ppm or more on a mass basis.

Examples of a method of setting the impurities in the above-described range include selecting a raw material having a low content of impurities as a raw material for each layer, preventing the impurities from being mixed in a case of forming each layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In each layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. The content of these compounds in each layer is preferably 100 ppm or less, more preferably 20 ppm or less, and particularly preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in each layer is preferably 0.01% by mass to 1.0% by mass and more preferably 0.05% by mass to 0.5% by mass.

### <<Specific Examples of Photosensitive Transfer Material>>

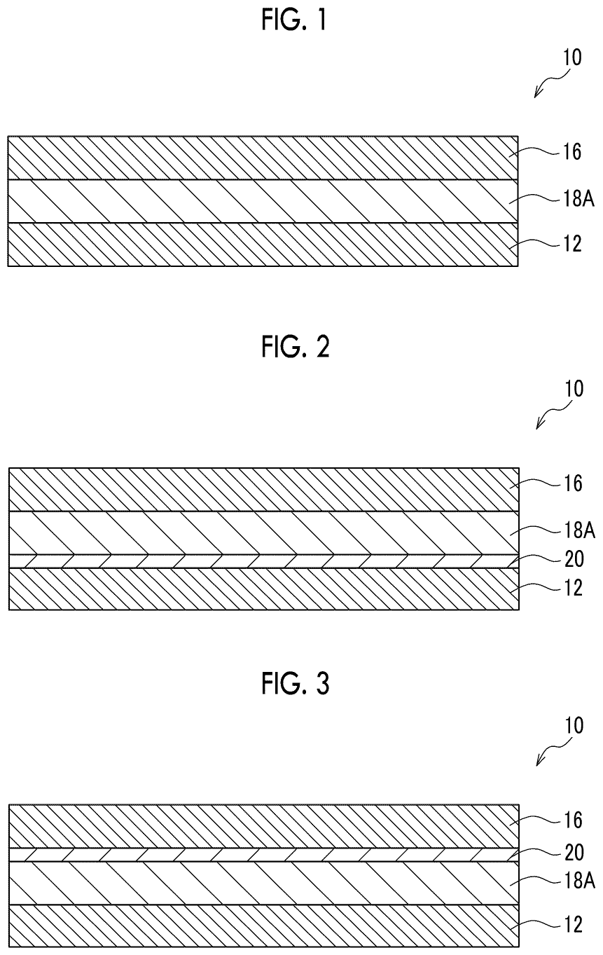

FIG. 1 is a schematic cross-sectional view showing a photosensitive transfer material 10 which is a specific example of the photosensitive transfer material according to the present disclosure. As shown in FIG. 1, the photosensitive transfer material 10 has a laminated structure of temporary support 12/photosensitive layer 18A/protective film 16 (that is, a laminated structure in which a temporary support 12, a photosensitive layer 18A, and a protective film 16 are arranged in this order).

In addition, FIG. 2 is a schematic cross-sectional view of a photosensitive transfer material 10 which is another specific example of the photosensitive transfer material according to the present disclosure. As shown in FIG. 2, the photosensitive transfer material 10 has a laminated structure of temporary support 12/antistatic layer 20/photosensitive layer 18A/protective film 16 (that is, a laminated structure in which a temporary support 12, an antistatic layer 20, a photosensitive layer 18A, and a protective film 16 are arranged in this order).

Furthermore, FIG. 3 is a schematic cross-sectional view of a photosensitive transfer material 10 which is still another specific example of the photosensitive transfer material according to the present disclosure. As shown in FIG. 3, the photosensitive transfer material 10 has a laminated structure of temporary support 12/photosensitive layer 18A/antistatic layer 20/protective film 16 (that is, a laminated structure in which a temporary support 12, a photosensitive layer 18A, an antistatic layer 20, and a protective film 16 are arranged in this order).

However, the photosensitive transfer material according to the present disclosure is not limited to the photosensitive transfer material 10, and for example, the protective film 16 may not be provided.

### [Manufacturing Method of Photosensitive Transfer Material]

A manufacturing method of the photosensitive transfer material is not particularly limited, but the photosensitive transfer material can be preferably manufactured by the manufacturing method of a photosensitive transfer material according to the present disclosure.

The manufacturing method of a photosensitive transfer material according to the present disclosure includes a step of preparing a temporary support and a step of forming a photosensitive layer by applying the photosensitive composition according to the present disclosure to one side of the temporary support.

A method for forming the photosensitive layer is not particularly limited, and a known method can be used.

As an example of the method for forming the photosensitive layer, a method forming the photosensitive layer by applying a photosensitive composition including a solvent onto a temporary support and then drying, as necessary is used.

As a coating method, a known method can be used.

Examples of the coating method include a printing method, a spray method, a roll coating method, a bar coating method, a curtain coating method, a spin coating method, and a die coating method (that is, a slit coating method).

Among these, a die coating method is preferable as the coating method.

As a drying method, known methods such as natural drying, heating drying, and drying under reduced pressure can be used, and these methods can be applied alone or in combination of plural thereof.

In the present disclosure, the “drying” means removing at least part of the solvent included in the composition.

The manufacturing method of a photosensitive transfer material may include a step of surface reforming a surface of the temporary support on the one side, between the step of preparing a temporary support and the step of forming a photosensitive layer.

For example, in order to improve adhesiveness between the temporary support and the photosensitive layer, the temporary support on a side in contact with the photosensitive layer may be surface reformed by ultraviolet (UV) irradiation, corona discharge, plasma, or the like.

In a case where the surface reforming is performed by UV irradiation, an exposure amount is preferably 10 mJ/cm² to 2,000 mJ/cm², more preferably 50 mJ/cm² to 1,000 mJ/cm², still more preferably 50 mJ/cm² to 500 mJ/cm², and particularly preferably 50 mJ/cm² to 200 mJ/cm². By setting the exposure amount within the above-described range, the adhesiveness between the photosensitive layer and the temporary support and the peelability of the protective film are excellent.

Examples of a light source for the UV irradiation include a low pressure mercury lamp, a high pressure mercury lamp, a ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 nm to 450 nm.

The light irradiation amount is not particularly limited, and an amount in the above-described range of exposure amount is preferable. In addition, the lamp output and the illuminance are not particularly limited.

The manufacturing method of the photosensitive transfer material may include a step of volatilizing ammonia described in a paragraph 0056 of WO2016/009980A, between the step of forming the photosensitive layer and the step of forming the protective film.

### (Film)

The film according to the present disclosure includes a layer containing a metal and a resin layer containing a binder polymer and the specific blocked isocyanate compound.

In a case where the film according to the present disclosure is formed by using the photosensitive transfer material according to the present disclosure, examples thereof include a film formed by transferring the photosensitive layer onto the layer containing a metal; a film formed by transferring and curing the photosensitive layer onto the layer containing a metal; a film formed by transferring and exposing the photosensitive layer onto the layer containing a metal to form a pattern and curing the layer; and a film formed by applying a photosensitive composition onto the layer containing a metal, drying the photosensitive composition to form a photosensitive layer, and exposing the photosensitive layer to form a pattern and curing the layer.

### <Layer Containing Metal>

The metal contained in the layer containing a metal is not particularly limited, and preferred examples thereof include a metal conductive material. As the metal conductive material, a known metal conductive material can be used.

Examples of the above-described metal include Al, Zn, Cu, Fe, Ni, Cr, Mo, Ag, and Au. Among these, it is preferable to contain Au, Ag, or Cu, it is more preferable to contain Au or Ag, and it is particularly preferable to contain Ag.

In addition, preferred examples of the above-described metal include metal fibers, more preferred examples thereof include silver fibers, and particularly preferred examples thereof include silver nanowires. In the above-described aspects, since deterioration is more likely to occur under wet-heat conditions, the effect of the present disclosure can be further exhibited.

A shape of the above-described metal is not particularly limited, and may be provided as a layer on one entire surface of the above-described substrate, or may have a desired patterned shape. Examples thereof include a mesh-shaped transparent electrode shape, and a wire shape such as a lead wire (so-called lead-out wire) disposed on a frame portion of the touch panel.

Among these, the above-described metal preferably includes metal fibers, and particularly preferably includes a layer including metal fibers (metal fiber layer). In addition, the above-described layer including metal fibers preferably has a desired pattern shape.

In addition, the above-described metal may be metal fine particles (for example, silver, copper, nickel, zinc oxide, tin oxide, indium oxide, and the like).

In the film according to the present disclosure, the layer containing a metal may be a layer consisting of a metal formed by a sputtering method or the like.

The layer containing a metal may contain a silver nanowire and a hydrophilic compound. The hydrophilic compound is not particularly limited, and may be, for example, a compound having a hydroxyl group or an acid group.

The above-described layer containing a metal may contain a carbon-based conductive material (for example, a carbon nanotube, a carbon nanofiber, or graphene), a conductive polymer (for example, poly(3,4-ethylenedioxythiophene) doped with poly(4-styrenesulfonic acid), polyaniline, or the like), or the like.

Examples of a shape of the metal fibers include a cylindrical shape, a rectangular parallelepiped shape, and a columnar shape having a polygonal cross section. The metal fibers preferably have at least one shape of a cylindrical shape or a columnar shape having a polygonal cross section in applications where high transparency is required.

The cross-sectional shape of the silver nanowires can be observed using, for example, a transmission electron microscope (TEM).

A diameter (so-called minor axis length) of the metal fibers is not particularly limited, but from the viewpoint of transparency, for example, it is preferably 50 nm or less, more preferably 35 nm or less, and still more preferably 20 nm or less.

From the viewpoint of oxidation resistance and migration durability, the lower limit of the diameter of the metal fibers is, for example, preferably 5 nm or more.

A length (so-called major axis length) of the metal fibers is not particularly limited, but from the viewpoint of conductivity, for example, it is preferably 5 μm or more, more preferably m or more, and still more preferably 30 μm or more.

From the viewpoint of suppressing formation of aggregates in the manufacturing process, the upper limit of the length of the metal fibers is preferably, for example, 1 mm or less.

The diameter and length of the metal fibers can be measured using, for example, a transmission electron microscope (TEM) or an optical microscope.

Specifically, the diameter and length of 300 randomly selected silver nanowires are measured from the metal fibers magnified and observed using a transmission electron microscope (TEM) or an optical microscope. Values obtained by arithmetically averaging the measured values are defined as the diameter and length of the silver nanowires.

A content of the metal fibers in the metal fiber layer (an example of the layer containing a metal) is not particularly limited, but for example, from the viewpoint of transparency and conductivity, it is preferably 1% by mass to 99% by mass, and more preferably 10% by mass to 95% by mass with respect to the total mass of the metal fiber layer.

The layer containing a metal may contain a binder (also referred to as “matrix”) as necessary.

The binder is a solid material in which the metal is dispersed or embedded.

Examples of the binder include polymer materials and inorganic materials.

As the binder, a material having light-transmitting property is preferable.

Examples of the polymer material include (meth)acrylic resins [for example, poly(methyl methacrylate)], polyesters [for example, polyethylene terephthalate (PET)], polycarbonates, polyimides, polyamides, polyolefins (for example, polypropylene), polynorbornenes, cellulose compounds, polyvinyl alcohol (PVA), and polyvinylpyrrolidone.

Examples of the cellulose compound include hydroxypropylmethyl cellulose (HPMC), hydroxyethyl cellulose (HEC), methyl cellulose (MC), hydroxypropyl cellulose (HPC), and carboxymethyl cellulose (CMC).

In addition, the polymer material may be a conductive polymer material.

Examples of the conductive polymer material include polyaniline and polythiophene.

Examples of the inorganic material include silica, mullite, and alumina.

In addition, as the binder, those described in paragraphs 0051 and 0052 of JP2014-212117A can also be used.

In a case where the layer containing a metal contains a binder, the layer containing a metal may contain only one kind of the binder, or may contain two or more kinds thereof.

In a case where the layer containing a metal contains a binder, a content of the binder in the layer containing a metal is preferably 1% by mass to 99% by mass and more preferably 5% by mass to 80% by mass with respect to the total mass of the layer containing a metal.

A thickness of the layer containing a metal is not particularly limited, but from the viewpoint of transparency and conductivity, it is preferably 1 nm to 400 nm and more preferably 10 nm to 200 nm. Within the above-described range, low resistance electrode can be formed relatively easily.

The thickness of the layer containing a metal is measured by the following method.

In a cross-sectional observation image of the layer containing a metal in the thickness direction, an arithmetic average value of thicknesses of the layer containing a metal, measured at five randomly selected points, is determined, and the obtained value is defined as the thickness of the layer containing a metal. The cross-sectional observation image of the layer containing a metal in the thickness direction can be obtained by using a scanning electron microscope (SEM).

In addition, a width of the layer containing a metal can also be measured in the same manner as the method of measuring the thickness of the layer containing a metal.

### <Resin Layer>

The resin layer contains a binder polymer and the specific blocked isocyanate compound. Since preferred aspects and preferred contents of the binder polymer and the specific blocked isocyanate compound are the same as those of the photosensitive composition according to the present disclosure, the description thereof will not be repeated here.

Regarding the contents of the components, “with respect to the total solid content of the photosensitive composition” is read as “with respect to the total mass of the resin layer”.

The resin layer can contain a polymerizable compound, a polymerization initiator, a heterocyclic compound, a thermal crosslinking compound, a surfactant, a hydrogen donating compound, a photoacid generator, a hygroscopic material, and other components.

Since preferred aspects and preferred contents of these components are the same as those of the photosensitive composition according to the present disclosure, the description thereof will not be repeated here.

The above-described resin layer is preferably a layer obtained by curing the photosensitive composition according to the present disclosure.

A thickness of the resin layer is not particularly limited and can be appropriately selected as desired, but for example, it is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

From the viewpoint of reliability, a content of a halide ion contained in the resin layer is preferably 1.5 ppm by mass or less, more preferably 1.2 ppm by mass or less, and most preferably 0.8 ppm by mass or less with respect to the total mass of the resin layer.

The above-described resin layer is preferably achromatic. Specifically, in CIE1976 (L*, a*, b*) color space, with respect to the total reflection (incidence angle: 8°, light source: D-65 (visual field: 2°)), the above-described resin layer preferably has an L* value of 10 to 90, an a* value of −1.0 to 1.0, and a b* value of −1.0 to 1.0.

From the viewpoint of rust prevention property, a moisture permeability of the above-described resin layer at a film thickness of 40 μm is preferably 500 g/(m²·24 hr) or less, more preferably 300 g/(m²·24 hr) or less, and still more preferably 100 g/(m²·24 hr) or less.

A shape of the above-described resin layer is not particularly limited, and may have a desired patterned shape.

Furthermore, the above-described resin layer may have an opening portion.

The opening portion can be formed by dissolving a non-exposed portion of the photosensitive layer in the photosensitive transfer material according to the present disclosure with a developer.

The above-described resin layer preferably contains a cured resin obtained by curing a curable component (the polymerizable compound, the photopolymerization initiator, the thermal crosslinking compound, and the like) in the above-described photosensitive layer by a reaction such as polymerization.

In addition, preferred aspects of components other than the curable component in the above-described resin layer are the same as the preferred aspects in the above-described photosensitive layer, and preferred contents of these components in the above-described resin layer are also the same as in the preferred aspects in the above-described photosensitive layer.

In addition, a preferred thickness of the above-described resin layer is the same as the preferred thickness of the above-described photosensitive layer.

A film forming method according to the present disclosure will be described later in a manufacturing method of a laminate including a substrate.

### (Capacitive Input Device)

In one embodiment, the capacitive input device according to the present disclosure has the cured film according to the present disclosure, and is preferably manufactured by using the photosensitive transfer material according to the present disclosure.

In another embodiment, the capacitive input device according to the present disclosure has the film according to the present disclosure, and is preferably manufactured by using the photosensitive transfer material according to the present disclosure.

In addition, the above-described capacitive input device is preferably a touch panel.

The touch panel according to the present disclosure preferably has the cured film according to the present disclosure or the film according to the present disclosure.

In addition, the capacitive input device according to the present disclosure is preferably a laminate obtained by laminating a substrate, an electrode which is the above-described layer containing a metal, and the above-described cured film in this order.

In addition, the capacitive input device according to the present disclosure is preferably a laminate obtained by laminating a substrate, an electrode which is the above-described layer containing a metal, and the above-described resin layer in this order. In this case, the above-described electrode and the above-described resin layer correspond to the film according to the present disclosure.

The substrate is the same as that in the manufacturing method of a laminate described later.

A preferred aspect of the electrode as the above-described layer containing a metal in the capacitive input device according to the present disclosure is the same as the preferred aspect of the above-described layer containing a metal in the film according to the present disclosure.

In addition, the above-described electrode may be a transparent electrode pattern or a lead wire. In addition, the above-described electrode is preferably an electrode pattern, and more preferably a transparent electrode pattern.

As the transparent electrode pattern, a layer containing metal fibers or a metal mesh layer is preferable, a layer containing metal fibers is more preferable, and the above-described silver nanowire layer is particularly preferable.

As a material of the lead wire, metal is preferable. Examples of a metal which is the material of the lead wire include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

A preferred aspect of the above-described resin layer in the capacitive input device according to the present disclosure is the same as the preferred aspect of the above-described resin layer in the film according to the present disclosure.

In addition, the above-described resin layer in the capacitive input device according to the present disclosure may have a desired pattern shape.

In addition, the capacitive input device according to the present disclosure, preferably the touch panel according to the present disclosure may include a refractive index-adjusting layer.

A preferred aspect of the refractive index-adjusting layer is the same as the preferred aspect of the refractive index-adjusting layer which can be included in the photosensitive transfer material.

The refractive index-adjusting layer may be formed by applying and drying a composition for forming the refractive index-adjusting layer, or may be formed by transferring the refractive index-adjusting layer of the photosensitive transfer material including the refractive index-adjusting layer.

The aspect in which the touch panel includes the refractive index-adjusting layer has an advantage that the metal conductive material and the like are hardly visible (that is, wire visibility is prevented).

In the capacitive input device according to the present disclosure, it is preferable that the capacitive input device includes the substrate, the transparent electrode pattern which is the above-described metal, the above-described resin layer disposed adjacent to the transparent electrode pattern, and the refractive index-adjusting layer disposed adjacent to the resin layer, in which a refractive index of the resin layer is higher than a refractive index of the refractive index-adjusting layer. In addition, the refractive index of the above-described resin layer is preferably 1.6 or more.

In a case where the capacitive input device according to the present disclosure has the above-described configuration, covering property of the transparent electrode pattern is improved.

As the wire for a touch panel, for example, the lead wire (lead-out wire) disposed on the frame portion of the touch panel is used. As a material of the wire for a touch panel, metal is preferable. Examples of a metal which is the material of the wire for a touch panel include gold, silver, copper, molybdenum, aluminum, titanium, chromium, zinc, manganese, and alloy formed of two or more kinds of these metal elements. Among these, as the metal which is the material of the wire for a touch panel, copper, molybdenum, aluminum, or titanium is preferable, and from the viewpoint of low electric resistance, copper is more preferable. On the other hand, since copper is easily oxidized and discolored, an antioxidant treatment may be performed to form a protective film (metal conductive material protective film).

With regard to the structure of the touch panel, a structure of a capacitive input device described in JP2014-10814A and JP2014-108541A may be referred to.

Preferred aspects of the lamination, the pattern exposure, and the development include the above-described preferred aspects.

The touch panel according to the present disclosure may include a UV-absorbing layer having absorption at a wavelength of 300 nm to 400 nm, in the layer configuration thereof. In a case where the UV-absorbing layer is provided, it is desirable that the UV-absorbing layer is on the visible side with respect to the photosensitive layer.

In the UV-absorbing layer, the sum of absorbances at a wavelength of 300 nm to 400 nm is preferably 10 or more and 500 or less, more preferably 150 or more and 500 or less, and still more preferably 300 or more and 500 or less.

As the UV-absorbing layer, a polarizer, OCA or a protective film to which a UV absorber is added, soda glass, or the like can be used.

### <<Specific Example of Touch Panel>>

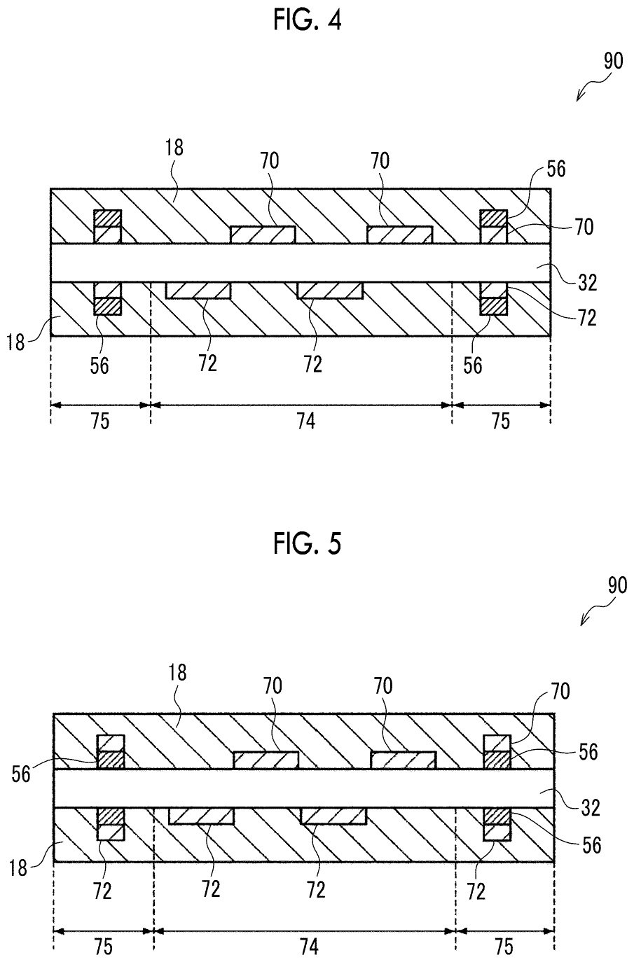

FIG. 4 is a schematic cross-sectional view of a touch panel 90 which is a first specific example of the touch panel according to the present disclosure.

As shown in FIG. 4, the touch panel 90 has an image display region 74 and an image non-display region 75 (that is, a frame portion).

In addition, the touch panel 90 includes an electrode for a touch panel on both surfaces of a substrate 32. Specifically, the touch panel 90 includes a first metal conductive material 70 on one surface of the substrate 32 and a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire.

In the touch panel 90, a metal conductive material protective film 18 is formed on one surface of the substrate 32 so as to cover the first transparent electrode pattern 70 and the lead wire 56, and a metal conductive material protective film 18 is formed on the other surface of the substrate 32 so as to cover the second metal conductive material 72 and the lead wire 56.

A refractive index-adjusting layer may be formed on one surface of the substrate 32.

In addition, FIG. 5 is a schematic cross-sectional view of a touch panel 90 which is a second specific example of the touch panel according to the present disclosure.

As shown in FIG. 5, the touch panel 90 has an image display region 74 and an image non-display region 75 (that is, a frame portion).

In addition, the touch panel 90 includes an electrode for a touch panel on both surfaces of a substrate 32. Specifically, the touch panel 90 includes a first metal conductive material 70 on one surface of the substrate 32 and a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire. In addition, the lead wire 56 is formed inside surrounded by the metal conductive material protective film 18, and the first metal conductive material 70 or the second metal conductive material 72.

In the touch panel 90, a metal conductive material protective film 18 is formed on one surface of the substrate 32 so as to cover the first transparent electrode pattern 70 and the lead wire 56, and a metal conductive material protective film 18 is formed on the other surface of the substrate 32 so as to cover the second metal conductive material 72 and the lead wire 56.

A refractive index-adjusting layer may be formed on one surface of the substrate 32.

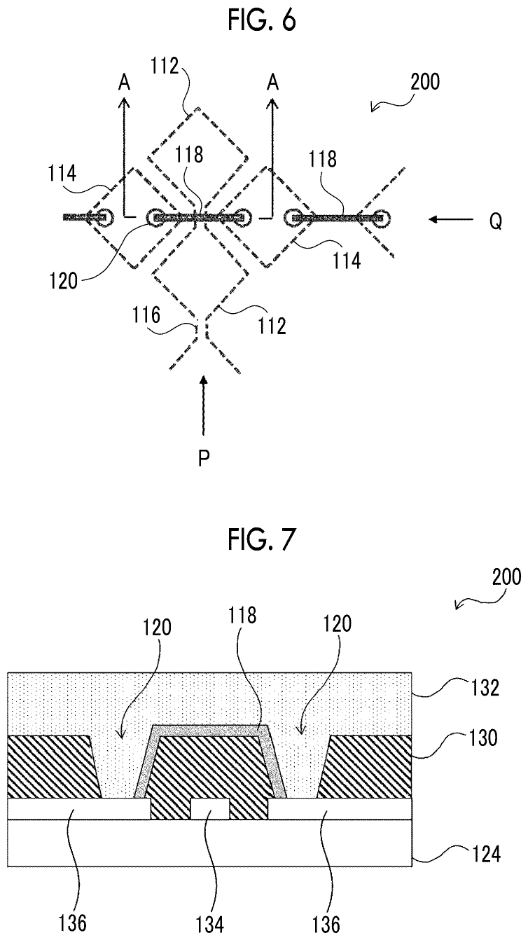

Another embodiment of the touch panel according to the present disclosure will be described with reference to FIGS. 6 and 7.

FIG. 6 is a schematic plan view showing another specific example of the touch panel according to the present disclosure, and FIG. 7 is a cross-sectional view taken along a line A-A of FIG. 6.

FIGS. 6 and 7 show a touch panel 200 having a transparent electrode pattern (including a first island-shaped electrode portion, a first wiring part 116, a second island-shaped electrode portion, and a bridge wire 118), a protective layer 130, and an overcoat layer 132 in this order on a transparent film substrate 124.

It is preferable that the protective layer 130 and the overcoat layer 132 are layers formed from the film according to the present disclosure or obtained by curing the film according to the present disclosure.

In addition, as shown in FIGS. 6 and 7, on the protective layer 130 disposed on the second island-shaped electrode portion 114 in the transparent electrode pattern on the transparent film substrate 124, a through hole 120 for connecting the second island-shaped electrode portion 114 and the bridge wire (second wiring part) 118 for bridging between two second island-shaped electrode portions 114 adjacent to each other and electrically connecting the second island-shaped electrode portions 114 to each other is formed.

The touch panel 200 has, on the transparent substrate 124, a first electrode pattern 134 and a second electrode pattern 136, which respectively extends in a direction of an arrow P or a direction of an arrow Q.

FIGS. 6 and 7 show only a part of the touch panel, but on the transparent substrate, the first electrode patterns 134 are arranged in one direction (first direction) over a wide range of the transparent substrate, and the second electrode patterns 136 are arranged in a direction (second direction) different from the first direction over a wide range of the transparent substrate.

In FIG. 6, the first electrode pattern 134 is disposed on the transparent substrate 124 such that a plurality of rectangular electrode parts (first island-shaped electrode portions) 112 are arranged in an island shape at equal intervals along the direction of the arrow P, and the first island-shaped electrode portions 112 adjacent to each other are continuously connected by the first wiring part 116. As a result, an elongated electrode is formed in one direction on the surface of the transparent substrate.

The first wiring part is preferably formed of the same material as the first island-shaped electrode portion.

In addition, in FIG. 6, the second electrode pattern 136 is disposed on the transparent substrate 124 such that rectangular electrode parts (second island-shaped electrode portions) 114 which are substantially the same as the first island-shaped electrode portion are arranged in an island shape at equal intervals along the direction of the arrow Q, which is substantially perpendicular to the direction of the arrow P, and the second island-shaped electrode portions 114 adjacent to each other are continuously connected by the second wiring part (bridge wire) 118.

As a result, an elongated electrode is formed in one direction different from the first electrode pattern on the surface of the transparent substrate.

As shown in FIGS. 6 and 7, the first electrode pattern 134 and the second electrode pattern 136 form a bridge structure in which one of intersecting electrodes jumps over the other at an intersecting portion so as to prevent the first electrode pattern 134 and the second electrode pattern 136 from conducting each other.

In the touch panel shown in FIG. 7, the protective layer 130 is disposed so as to cover the first electrode pattern 34 and the second electrode pattern 136.

### (Laminate)

The laminate according to the present disclosure includes a substrate having a surface on which a layer containing a metal is provided, and the cured film according to the present disclosure or the film according to the present disclosure in this order. The laminate may include a UV-absorbing layer.

Preferred aspects of the substrate, the UV-absorbing layer, and the like in the laminate according to the present disclosure are the same as the preferred aspects of the substrate, the UV-absorbing layer, and the like described above.

The resin layer of the cured film or the film in the laminate according to the present disclosure is a layer obtained by curing the above-described photosensitive composition or a layer obtained by forming a pattern of the above-described photosensitive composition as necessary and curing the pattern.

Since a preferred aspect of the resin layer of the cured film or the film in the laminate according to the present disclosure is described above, the description thereof will not be repeated here.

Other elements in the laminate according to the present disclosure can also be provided with reference to the above-described touch panel or the like.

### (Manufacturing Method of Laminate)

The manufacturing method of the laminate according to the present disclosure is not particularly limited as long as it is a method using the photosensitive composition or the photosensitive transfer material according to the present disclosure, and for example, the following manufacturing method of the laminate according to the present disclosure can be suitably used.

The manufacturing method of the laminate according to the present disclosure includes, in the following order, a step of applying the photosensitive composition according to the present disclosure onto a base material having a layer containing a metal on a surface thereof to form a photosensitive layer (also referred to as “photosensitive layer forming step”), a step of exposing the photosensitive layer in a patterned manner (also referred to as “pattern exposure step”), and a step of developing the photosensitive layer to form a pattern (also referred to as “development step”).

In another aspect, the manufacturing method of the laminate according to the present disclosure includes, in the following order, a step of transferring at least the photosensitive layer in the photosensitive transfer material according to the present disclosure to a base material having a layer containing a metal on a surface thereof (also referred to as “photosensitive layer forming step”), a step of exposing the photosensitive layer in a patterned manner (also referred to as “pattern exposure step”), and a step of developing the photosensitive layer to form a pattern (also referred to as “development step”).

Hereinafter, each step in the manufacturing method of the laminate according to the present disclosure will be described.

### <Photosensitive Layer Forming Step>

The photosensitive layer forming step may be a step of transferring at least the above-described photosensitive layer in the photosensitive transfer material according to the present disclosure to the base material having the layer containing a metal on a surface thereof.

In the photosensitive layer forming step, the photosensitive transfer material according to the present disclosure is laminated on the surface of the base material having the layer containing a metal, and the photosensitive layer in the photosensitive transfer material according to the present disclosure is transferred onto the surface, thereby forming the photosensitive layer on the surface.

The laminating (so-called transfer of the photosensitive layer) can be performed using a known laminator such as a vacuum laminator or an auto-cut laminator.

As a laminating condition, a general condition can be applied.

A laminating temperature is preferably 80° C. to 150° C., more preferably 90° C. to 150° C., and still more preferably 100° C. to 150° C.

In a case of using a laminator including a rubber roller, the laminating temperature indicates a temperature of the rubber roller.

A temperature of the base material in a case of laminating is not particularly limited.

The temperature of the base material in a case of laminating is preferably 10° C. to 150° C., more preferably 20° C. to 150° C., and still more preferably 30° C. to 150° C.

In a case of using a resin base material as the base material, the temperature of the base material in a case of laminating is preferably 10° C. to 80° C., more preferably 20° C. to 60° C., and still more preferably 30° C. to 50° C.

In addition, a linear pressure in a case of laminating is preferably 0.5 N/cm to 20 N/cm, more preferably 1 N/cm to 10 N/cm, and still more preferably 1 N/cm to 5 N/cm.

In addition, a transportation speed (laminating speed) in a case of laminating is preferably 0.5 m/min to 5 m/min and more preferably 1.5 m/min to 3 m/min.

In a case of using a photosensitive transfer material having a laminated structure of protective film/photosensitive layer/interlayer/thermoplastic resin layer/temporary support, first, the protective film is peeled off from the photosensitive transfer material to expose the photosensitive layer, the photosensitive transfer material and the base material are bonded together such that the exposed photosensitive layer and the surface of the layer containing a metal are in contact with each other, and then heating and pressurization are performed. By such an operation, the photosensitive layer of the photosensitive transfer material is transferred onto the surface of the layer containing a metal, and thus a film having a laminated structure of temporary support/thermoplastic resin layer/interlayer/photosensitive layer/layer containing a metal/base material is formed. In the laminated structure, the portion of “layer containing a metal/base material” is the base material having the layer containing a metal on the surface.

Thereafter, as necessary, the temporary support is peeled off from the laminate having the above-described laminated structure. However, the pattern exposure which will be described later can be also performed by leaving the temporary support.

As an example of the method of transferring the photosensitive layer of the photosensitive transfer material on the base material and performing the pattern exposure and the development, a description in paragraphs 0035 to 0051 of JP2006-23696A can also be referred to.

In another aspect, the photosensitive layer forming step may be a step of forming the photosensitive layer by applying the photosensitive composition according to the present disclosure onto the base material having the layer containing a metal on a surface thereof. As a method of applying the photosensitive composition onto the base material, the above-described manufacturing method of the photosensitive transfer material can be used.

Examples of the base material used in the manufacturing method of the laminate according to the present disclosure include base materials of various materials having the layer containing a metal on a surface thereof, for example, a resin base material, a glass base material, a metal base material, and a silicon base material, and a known structure of an electrode or the like may be further provided on a surface of the base material and inside the base material.

Among these, a glass base material or a resin base material is preferable as the above-described base material.

In addition, the base material is preferably a transparent base material and more preferably a transparent resin base material. The “transparent” in the present disclosure means that the transmittance of all visible light is 85% or more, preferably 90% or more, and more preferably 95% or more.

A refractive index of the base material is preferably 1.50 to 1.52.

As the glass base material, tempered glass such as GORILLA GLASS (registered trademark) manufactured by Corning Incorporated can be used. A thickness of the glass base material is preferably 0.01 mm or more and 1.1 mm or less, and more preferably 0.1 mm or more and 0.7 mm or less.

As the resin base material, at least one of a component with no optical strains or a component having high transparency is preferably used, and examples thereof include a base material containing a resin such as polyethylene terephthalate (PET), polyethylene naphthalate (PEN), polycarbonate (PC), triacetyl cellulose (TAC), polyimide (PI), polybenzoxazole (PBO), and cycloolefin polymer (COP). From the viewpoint of strength and flexibility, a thickness of the resin base material is preferably 1.0 μm or more and 100 μm or less, and more preferably 5.0 μm or more and 50 μm or less.

As the material of the transparent material, materials described in JP2010-86684A, JP2010-152809A, and JP2010-257492A are preferably used.

The layer containing a metal is as described above in the photosensitive transfer material.

### <Pattern Exposure Step>

The pattern exposure step is a step of performing a pattern exposure of the above-described photosensitive layer after the above-described photosensitive layer forming step.

The “pattern exposure” refers to exposure of the aspect of performing the exposure in a patterned manner, that is, the embodiment in which an exposed portion and an unexposed portion are present.

For example, in a case where the photosensitive layer is a negative tone, the exposed portion in the pattern exposure of the photosensitive layer on the base material is cured to finally form a cured film. Meanwhile, the unexposed portion of the photosensitive layer on the base material in the pattern exposure is not cured, and is dissolved and removed with a developer in the subsequent development step. With the unexposed portion, the opening portion of the cured film can be formed after the development step.

The pattern exposure may be an exposure through a mask or may be a digital exposure using a laser or the like.

In a case where the photosensitive layer does not need to be patterned, the laminate can also be manufactured by, for example, exposing the entire surface of the photosensitive layer instead of the present pattern exposure step.

As a light source of the pattern exposure, a light source can be appropriately selected, as long as it can emit light at a wavelength region (for example, 365 nm or 405 nm) at which the photosensitive layer can be cured.

Examples of the light source include various lasers, a light emitting diode (LED), an ultra-high pressure mercury lamp, a high pressure mercury lamp, and a metal halide lamp.

An exposure amount is preferably 5 mJ/cm² to 200 mJ/cm² and more preferably 10 mJ/cm² to 200 mJ/cm².

In a case where the photosensitive layer is formed on the base material using the photosensitive transfer material, the pattern exposure may be performed after peeling the temporary support, or the temporary support may be peeled off after performing the pattern exposure before peeling off the temporary support.

In addition, in the exposure step, the heat treatment (so-called post exposure bake (PEB)) may be performed with respect to the photosensitive layer after the pattern exposure and before the development.

### <Development Step>

The development step is a step of developing the above-described photosensitive layer after the above-described pattern exposure step (that is, by dissolving the unexposed portion in the pattern exposure in a developer) to form a pattern.

A developer used in the development is not particularly limited, and a well-known developer such as a developer disclosed in JP1993-72724A (JP-H5-72724A) can be used.

As the developer, an alkali aqueous solution is preferably used.

Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to the total mass of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, F-caprolactam, and N-methylpyrrolidone.

A concentration of the organic solvent is preferably 0.1% by mass to 30% by mass.

The developer may include a known surfactant.

A concentration of the surfactant is preferably 0.01% by mass to 10% by mass.

A liquid temperature of the developer is preferably 20° C. to 40° C.

Examples of the development method include methods such as puddle development, shower development, shower and spin development, and dip development.

In a case of the shower development, an uncured portion of the photosensitive layer is removed by spraying the developer to the photosensitive layer after the pattern exposure as a shower.

In a case of using the photosensitive transfer material including at least one of the photosensitive layer, the thermoplastic resin layer, or the interlayer, after the transfer of these layers onto the base material and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance, or the thermoplastic resin layer and the interlayer may be removed at the same time as the uncured portion.

In addition, after the development, the development residue is preferably removed by spraying a washing agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the base material is the resin base material, a temperature of the post baking is preferably 100° C. to 160° C. and more preferably 130° C. to 160° C.

A resistance value of the transparent electrode pattern can also be adjusted by this post baking.

In a case where the photosensitive layer contains a carboxy group-containing (meth)acrylic resin, at least a part of the carboxy group-containing (meth)acrylic resin can be changed to carboxylic acid anhydride by the post baking. In a case of being changed in this way, developability and hardness of the cured film are excellent.

The development step may include a stage of performing the development, and a stage of exposing the cured film obtained by the development (hereinafter, also referred to as “post exposure”).

In a case where the development step includes both a stage of performing the post exposure and a stage of performing the post baking, it is preferable to perform the post-baking after the post-exposure.

With regard to the pattern exposure and the development, for example, a description described in paragraphs 0035 to 0051 of JP2006-23696A can be referred to.

The manufacturing method of the laminate according to the present disclosure may include a step of patterning the metal on the surface of the base material, before the step of forming the photosensitive layer or the step of transferring the photosensitive layer (that is, the photosensitive layer forming step). In a case of patterning the metal, the possibility that impurities in the metal are released to the outside of the metal is increased, but since the impurities released in this manner can be captured by the cured film formed of the photosensitive composition according to the present disclosure, it is easy to improve migration durability. A method of patterning the metal is not particularly limited, and a known etching method may be used.

The manufacturing method of the laminate according to the present disclosure may include a step (so-called other steps) other than the steps described above.

Examples of the other step include a known step (for example, washing step) which may be provided in a normal photolithography step.

### (Deterioration Suppressing Method)

The deterioration suppressing method according to the present disclosure is a method for suppressing deterioration of the metal in the film including the layer containing a metal and the resin layer, in which the resin layer contains the binder polymer and the specific blocked isocyanate compound.

In a case where the above-described film is formed of the photosensitive transfer material according to the present disclosure, examples thereof include a film obtained by transferring the photosensitive layer to the layer containing a metal; a film obtained by transferring and curing the photosensitive layer to the layer containing a metal; and a film obtained by transferring and exposing the photosensitive layer to the layer containing a metal to form a pattern and curing the photosensitive layer.

The specific blocked isocyanate compound in the resin layer of the above-described film has the same meaning as the specific blocked isocyanate compound in the photosensitive layer of the photosensitive transfer material according to the present disclosure, and the same applies to the preferred aspect thereof.

A content of the specific blocked isocyanate compound and a content of the hygroscopic material in the above-described resin layer are the same as those described above regarding the photosensitive layer, and the content of the components is read as “with respect to the total solid content of the resin layer” instead of “with respect to the total mass of the photosensitive layer”.

Suitable examples of the film including the layer containing a metal and the resin layer in the deterioration suppressing method according to the present disclosure include the film according to the present disclosure.

In the deterioration suppressing method according to the present disclosure, it is preferable to use the photosensitive transfer material according to the present disclosure.

In a case where the above-described film is formed of the photosensitive transfer material according to the present disclosure, examples thereof include a film obtained by transferring the photosensitive layer to the layer containing a metal; a film obtained by transferring and curing the photosensitive layer to the layer containing a metal; and a film obtained by transferring and exposing the photosensitive layer to the layer containing a metal to form a pattern and curing the photosensitive layer.

The above-described layer containing a metal in the deterioration suppressing method according to the present disclosure has the same meaning as the layer containing a metal in the film according to the present disclosure, and the same applies to the preferred aspect thereof.

The above-described resin layer in the deterioration suppressing method according to the present disclosure has the same meaning as the resin layer in the film according to the present disclosure, and the same applies to the preferred aspect thereof.

### EXAMPLES

Hereinafter, the present disclosure will be described in more detail with reference to Examples.

The material, the amount used, the ratio, the process contents, the process procedure, and the like shown in the following examples can be appropriately changed, within a range not departing from a gist of the present disclosure. Accordingly, the range of the present disclosure is not limited to specific examples shown below.

### [Preparation of Photosensitive Composition and Composition for Interlayer]

Photosensitive compositions A-1 to A-10 were prepared as described in Table 1, and a composition B-1 for an interlayer was prepared as described in Table 2. The numerical value in each component column in Tables 1 and 2 represents parts by mass.

TABLE 1

| Composition for forming photosensitive layer | | A-1 | A-2 | A-3 | A-4 | A-5 |
|---|---|---|---|---|---|---|
| Polymerizable | 1,9-nonanediol diacrylate (A-NOD-N, manufactured by Shin-Nakamura | 8.80 | 8.04 | 6.30 | 8.04 | 8.04 |
| compound | Chemical Co., Ltd.) | | | | | |
| Binder polymer | PGMEA solution of 27% by mass P-1 | 53.16 | 53.16 | 53.16 | 53.16 | 53.16 |
| Photopolymerization | 1-(biphenyl-4-y1)-2-methyl-2-morpholinopropan-1-one | 0.53 | 0.53 | 0.53 | 0.53 | 0.37 |
| initiator | (Api-307, manufactured by Shenzhen UV-ChemTech Co., Ltd.) | | | | | |
| | 2-(dimethylamino)-2-(4-methyl-benzyl)-1-(4-morpholin-4-yl-phenyl)- | | | | | 0.16 |
| | butan-1-one | | | | | |
| | (Omnirad 379EG, manufactured by IGM Resins B.V.) | | | | | |
| Thio compound | 2-Naphthalenethiol (manufactured by Tokyo Chemical Industry Co., Ltd.) | 0.007 | 0.007 | 0.007 | 0.007 | 0.007 |
| Blocked isocyanate | Karenz AOI-SM (manufactured by SHOWA DENKO K.K.) | 1.25 | 2.01 | 3.75 | | |
| compound | Karenz AOI-PAP (manufactured by SHOWA DENKO K.K.) | | | | 2.01 | |
| | Karenz MOI-SM (manufactured by SHOWA DENKO K.K.) | | | | | 2.01 |
| | Karenz AOI-AM (manufactured by SHOWA DENKO K.K.) | | | | | |
| | Karenz AOI-BP (manufactured by SHOWA DENKO K.K.) | | | | | |
| | DURANATE TPA-B80E (manufactured by Asahi Kasei Corporation) | | | | | |
| | (80% by mass ethyl acetate solution) | | | | | |
| Surfactant | S-506 (manufactured by DIC Corporation) (20% by mass PGMEA | 0.07 | 0.07 | 0.07 | 0.07 | 0.07 |
| | solution) | | | | | |
| | S-324 (manufactured by DIC Corporation) (20% by mass PGMEA | 0.23 | 0.23 | 0.23 | 0.23 | 0.23 |
| | solution) | | | | | |
| Solvent | Methyl ethyl ketone (MEK) | 35.9 | 35.9 | 35.9 | 35.9 | 35.9 |

| Composition for forming photosensitive layer | | A-6 | A-7 | A-8 | A-9 | A-10 |
|---|---|---|---|---|---|---|
| Polymerizable | 1,9-nonanediol diacrylate (A-NOD-N, manufactured by Shin-Nakamura | 8.04 | 10.05 | 5.55 | 8.04 | 8.04 |
| compound | Chemical Co., Ltd.) | | | | | |
| Binder polymer | PGMEA solution of 27% by mass P-1 | 53.16 | 53.16 | 53.16 | 53.16 | 53.16 |
| Photopolymerization | 1-(biphenyl-4-y1)-2-methyl-2-morpholinopropan-1-one | 0.53 | 0.53 | 0.53 | 0.53 | 0.53 |
| initiator | (Api-307, manufactured by Shenzhen UV-ChemTech Co., Ltd.) | | | | | |
| | 2-(dimethylamino)-2-(4-methyl-benzyl)-1-(4-morpholin-4-yl-phenyl)- | | | | | |
| | butan-1-one | | | | | |
| | (Omnirad 379EG, manufactured by IGM Resins B.V.) | | | | | |
| Thio compound | 2-Naphthalenethiol (manufactured by Tokyo Chemical Industry Co., Ltd.) | 0.007 | 0.007 | 0.007 | 0.007 | 0.007 |
| Blocked isocyanate | Karenz AOI-SM (manufactured by SHOWA DENKO K.K.) | | | 4.50 | | |
| compound | Karenz AOI-PAP (manufactured by SHOWA DENKO K.K.) | | | | | |
| | Karenz MOI-SM (manufactured by SHOWA DENKO K.K.) | | | | | |
| | Karenz AOI-AM (manufactured by SHOWA DENKO K.K.) | 2.01 | | | | |
| | Karenz AOI-BP (manufactured by SHOWA DENKO K.K.) | | | | 2.01 | |
| | DURANATE TPA-B80E (manufactured by Asahi Kasei Corporation) | | | | | 2.51 |
| | (80% by mass ethyl acetate solution) | | | | | |
| Surfactant | S-506 (manufactured by DIC Corporation) (20% by mass PGMEA | 0.07 | 0.07 | 0.07 | 0.07 | 0.07 |
| | solution) | | | | | |
| | S-324 (manufactured by DIC Corporation) (20% by mass PGMEA | 0.23 | 0.23 | 0.23 | 0.23 | 0.23 |
| | solution) | | | | | |
| Solvent | Methyl ethyl ketone (MEK) | 35.9 | 35.9 | 35.9 | 35.9 | 35.4 |

TABLE 2

| Composition for interlayer | B-1 |
|---|---|
| Deionized water | 38.1 |
| Methanol | 57.2 |
| Polyvinylpyrrolidone K-30 | 3.08 |
| (manufactured by Nippon Shokubai Co., Ltd.) | |
| METOLOSE SH-03 | 0.024 |
| (manufactured by Shin-Etsu Chemical Co., Ltd.) | |
| KURARAY POVAL 4-88LA | 1.60 |
| (manufactured by KURARAY CO., LTD.) | |
| F-444 (manufactured by DIC Corporation) | 0.004 |

Details of the abbreviations and the like described in Tables 1 and 2 are shown below.

### <Binder Polymer>

Compound P-1: polymer having the following structure, weight-average molecular weight: 27,000, ClogP value=2.17, the following numerical values indicate compositional ratios (molar ratios); in the table, PGMEA means propylene glycol monomethyl ether acetate.

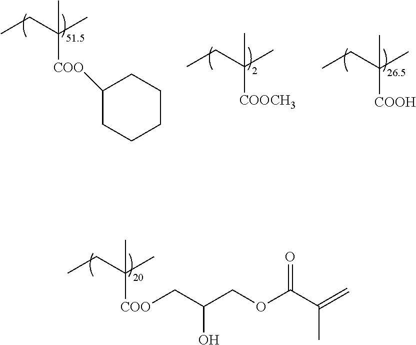

The compound P-1 was prepared by the following polymerization step and addition step.

### —Polymerization Step—

Propylene glycol monomethyl ether acetate (manufactured by Sanwa Chemical Industrial Co., Ltd., PGMEA) (60 g) and propylene glycol monomethyl ether (manufactured by Sanwa Chemical Industrial Co., Ltd., product name: PGM) (240 g) were introduced into a 2,000 mL flask. The obtained liquid was heated to 90° C. while stirring at a stirring speed of 250 rpm (round per minute; the same applies hereinafter). For the preparation of a dropping liquid (1), 107.1 g of methacrylic acid (manufactured by Mitsubishi Rayon Co., Ltd., product name: Acryester M), 5.46 g of methyl methacrylate (manufactured by Mitsubishi Gas Chemical Company, Inc., product name MMA), and 231.42 g of cyclohexyl methacrylate (manufactured by Mitsubishi Gas Chemical Co., Ltd., product name: CHMA) were mixed and diluted with 60 g of PGMEA to obtain the dropping liquid (1).

9.637 g of dimethyl 2,2′-azobis(2-methylpropionate) (manufactured by FUJIFILM Wako Pure Chemical Corporation, product name: V-601) was dissolved in 136.56 g of PGMEA to obtain a dropping liquid (2).

The dropping liquid (1) and the dropping liquid (2) were simultaneously added dropwise to the above-described 2,000 mL flask (specifically, the 2,000 mL flask containing the liquid heated to 90° C.) over 3 hours.

Next, the container of the dropping liquid (1) was washed with 12 g of PGMEA, and the washing solution was added dropwise to the above-described 2,000 mL flask. Next, the container of the dropping liquid (2) was washed with 6 g of PGMEA, and the washing solution was added dropwise to the above-described 2,000 mL flask. During the dropwise addition, the reaction solution in the above-described 2,000 mL flask was kept at 90° C. and stirred at a stirring speed of 250 rpm. Furthermore, as a post-reaction, the mixture was stirred at 90° C. for 1 hour.

2.401 g of V-601 was added to the reaction solution after the post-reaction as a first additional addition of an initiator. Furthermore, the container of V-601 was washed with 6 g of PGMEA, and the washing solution was introduced into the reaction solution. Thereafter, the reaction solution was stirred at 90° C. for 1 hour.

Next, 2.401 g of V-601 was added to the reaction solution as a second additional addition of the initiator. Furthermore, the container of V-601 was washed with 6 g of PGMEA, and the washing solution was introduced into the reaction solution. Thereafter, the reaction solution was stirred at 90° C. for 1 hour.

Next, 2.401 g of V-601 was added to the reaction solution as a third additional addition of the initiator. Furthermore, the container of V-601 was washed with 6 g of PGMEA, and the washing solution was introduced into the reaction solution.

Thereafter, the reaction solution was stirred at 90° C. for 3 hours.

### —Addition Step—

After stirring at 90° C. for 3 hours, 178.66 g of PGMEA was introduced into the reaction solution. Next, 2.7 g of tetraethylammonium acetate (manufactured by FUJIFILM Wako Pure Chemical Corporation) and 0.8 g of hydroquinone monomethyl ether (manufactured by FUJIFILM Wako Pure Chemical Corporation) were added to the reaction solution. Furthermore, each container was washed with 6 g of PGMEA, and the washing solution was introduced into the reaction solution. Thereafter, the reaction solution was heated to 100° C.

Next, 76.03 g of glycidyl methacrylate (manufactured by NOF Corporation, product name: Blemmer GH) was added dropwise to the reaction solution over 1 hour. The container of Blemmer GH was washed with 6 g of PGMEA, and the washing solution was introduced into the reaction solution. Thereafter, the mixture was stirred at 100° C. for 6 hours as an addition reaction.

Next, the reaction solution was cooled and filtered through a mesh filter (100 mesh) for removing dust, thereby obtaining 1,158 g of a solution of a compound P-1. The obtained solution of the compound P-1 was dried, the solvent was evaporated, and the resultant was re-dissolved in PGEMA to obtain a solution of the compound P-1 having a concentration of solid contents of 27.0% by mass. The obtained compound P-1 had a weight-average molecular weight of 27,000, a number-average molecular weight of 15,000, and an acid value of 95 mgKOH/g.

### <Blocked Isocyanate Compound>

Details of the blocked isocyanate compounds shown in Table 1 are as shown in Table 3.

DURANATE TPA-B80E is a compound in which an isocyanate body of hexamethylene diisocyanate is blocked with methyl ethyl ketone (MEK) oxime.

TABLE 3

| | | Dissociation | |
|---|---|---|---|
| | Structure | temperature | CAS RN |
| Karenz AOI-BP | 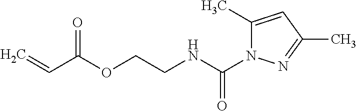 [SMILES: C=CC(=O)OCCNC(=O)n1nc(C)cc1C] | 130~140° C. | 885331-05-5 |
| Karenz AOI-SM | 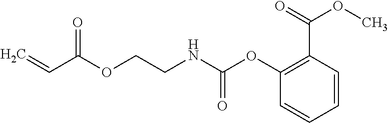 [SMILES: C=CC(=O)OCCNC(=O)Oc1ccccc1C(=O)OC] | 110~130° C. | 2633679-96-4 |
| Karenz AOI-AM | 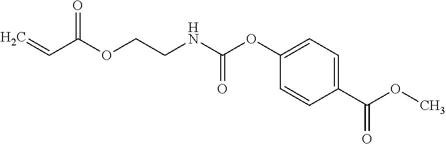 [SMILES: C=CC(=O)OCCNC(=O)Oc1ccc(C(=O)OC)cc1] | 120~140° C. | 633679-95-3 |
| Karenz MOI-SM | 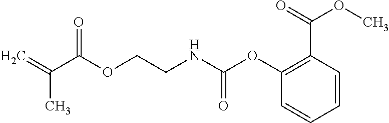 [SMILES: C=C(C)C(=O)OCCNC(=O)Oc1ccccc1C(=O)OC] | 110~130° C. | 89770-84-3 |
| Karenz AOI-PAP | 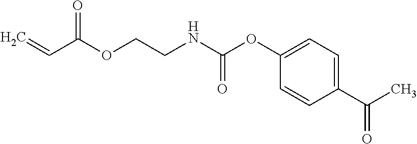 [SMILES: C=CC(=O)OCCNC(=O)Oc1ccc(C(C)=O)cc1] | — | 2633679-97-5 |

### Examples 1 to 7 and Comparative Examples 1 to 3

A temporary support LUMIRROR 16KS40 (thickness: 16 μm, manufactured by Toray Industries, Inc., polyethylene terephthalate film) was subjected to a surface reforming treatment by performing a corona discharge treatment for 3 seconds under conditions of an output voltage of 100%, an output of 250 W, a wire electrode having a diameter of 1.2 mm, an electrode length of 240 mm, and a distance between a work electrode and the electrode of 1.5 mm using a high-frequency oscillator.

Next, the obtained surface-reformed base material surface was coated with the photosensitive composition described in Table 4 using a slit-shaped nozzle, and then the solvent was volatilized in a drying zone at 120° C. to form a photosensitive layer. The coating amount of the photosensitive composition was adjusted to be the thickness of the photosensitive layer shown in Table 1.

Next, a protective film (LUMIRROR 16KS40, thickness: 16 μm, manufactured by Toray Industries, Inc., polyethylene terephthalate film) was bonded to the above-described photosensitive layer using a laminating machine at 50° C. and a pressure of 0.5 MPa, thereby producing photosensitive transfer materials of Examples 1 to 7 and Comparative Examples 1 to 3. Each of the above-described photosensitive transfer materials included a temporary support, a photosensitive layer, and a protective film in this order. [0321](Examples 8 and 9) The composition B-1 for an interlayer, described in Table 2, was applied onto a temporary support LUMIRROR 16KS40 (thickness: 16 μm, manufactured by Toray Industries, Inc., polyethylene terephthalate film) using a slit-shaped nozzle, and then the solvent was volatilized in a drying zone at 120° C. to form an interlayer.

Furthermore, the interlayer was coated with the photosensitive composition described in Table 4 using a slit-shaped nozzle, and then the solvent was volatilized in a drying zone at 120° C. to form a photosensitive layer.

The coating amount of the composition for an interlayer and the coating amount of the photosensitive composition were adjusted to the layer thicknesses of the interlayer and the photosensitive layer shown in Table 4.

Next, a protective film (LUMIRROR 16KS40, thickness: 16 μm, manufactured by Toray Industries, Inc., polyethylene terephthalate film) was bonded to the above-described photosensitive layer using a laminating machine at 50° C. and a pressure of 0.5 MPa, thereby producing photosensitive transfer materials of Examples 8 and 9. Each of the above-described photosensitive transfer materials included a temporary support, an adhesion-imparting layer, a photosensitive layer, and a protective film in this order.

### <Measurement of Storage Elastic Modulus>

In each of the photosensitive transfer materials of Examples 1 to 9 and Comparative Examples 1 to 3, the protective film was peeled off, and the exposed photosensitive layer was cut out in a size of 5 mm×30 mm. The cut-out sample was conditioned at 25° C. and 60% relative humidity (RH) for 2 hours or more, and then measured with a dynamic viscoelasticity measuring device (VIBRON: DVA-225 (manufactured by IT Keisoku Seigyo K.K.)) at a distance of 20 mm between grips, a temperature rising rate of 2° C./min, a measurement temperature range of 30° C. to 150° C., and a frequency of 1 Hz with respect to a longitudinal direction of the sample to obtain a storage elastic modulus at a temperature of 35° C. With the measured storage elastic modulus, the evaluation was carried out based on the following evaluation standards. The results are shown in Table 4.

### (Evaluation Standard)

A: storage elastic modulus was 5 GPa or more.
B: storage elastic modulus was 4 GPa or more and less than 5 GPa.

C: storage elastic modulus was less than 4 GPa.

### <Measurement of Content of Chloride Ion>

For each of the photosensitive transfer materials of Examples 1 to 9 and Comparative Examples 1 to 3, after peeling off the protective film, the exposed surface of the photosensitive layer was laminated on glass having a thickness of 1.1 mm to obtain a laminate having a structure of temporary support/photosensitive layer/glass base material.

As laminating conditions, a roll temperature was set as 110° C., a linear pressure was set as 0.6 MPa, and a linear velocity (laminating speed) was set as 2.0 m/min.

Using a proximity type exposure machine (manufactured by Hitachi High-Tech Electronic Engineering Corporation) having an ultra-high pressure mercury lamp, each of the above-described laminates was exposed with an exposure amount of 480 mJ/cm² (i ray), without peeling off the temporary support. After the exposure, the temporary support of each of the above-described laminates was peeled off after being left to stand for 1 hour, and the photosensitive layer was further exposed at an exposure amount of 1,000 mJ/cm² (i ray) to be cured.

100 mg of the cured photosensitive layer was scraped off and collected. 100 mg of the collected sample was dissolved in 5 mL of propylene glycol monomethyl ether acetate. 5 mL of ultrapure water was added thereto, and the mixture was stirred for 2 hours. The mixture was left to stand for 12 hours or more, 1 mL of the aqueous layer was collected, and 9 mL of ultrapure water was added thereto to prepare a sample for measurement.

The prepared sample for measurement was subjected to ion chromatograph according to the measuring device and measuring conditions shown below, thereby measuring and calculating the content of the halide ion. The results are shown in Table 4.
Ion chromatograph device: IC-2010 (manufactured by Tosoh Corporation)
Analytical column: TSKgel SuperIC-Anion HS
Guard column: TSKgel guard column SuperIC-A HS-Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (using suppressor)

### <<Production of Laminate>>

For each of the photosensitive transfer materials of Examples 1 to 9 and Comparative Examples 1 to 3, the protective film was peeled off, and the exposed surface of the photosensitive layer was laminated on a silver nanowire layer side of a film having a silver nanowire layer on a cycloolefin polymer base material to obtain a laminate having a structure of temporary support/photosensitive layer/silver nanowire layer/base material.

As laminating conditions, a roll temperature was set as 110° C., a linear pressure was set as 0.6 MPa, and a linear velocity (laminating speed) was set as 2.0 m/min.

Using a proximity type exposure machine (manufactured by Hitachi High-Tech Electronic Engineering Corporation) having an ultra-high pressure mercury lamp, each of the above-described laminates was exposed with an exposure amount of 480 mJ/cm² (i ray), without peeling off the temporary support. After the exposure, the temporary support of each of the above-described laminates was peeled off after being left to stand for 1 hour, and the photosensitive layer was further exposed at an exposure amount of 1,000 mJ/cm² (i ray) to be cured, thereby obtaining a cured layer to produce each laminate.

### —UV Light Resistance Test—

The laminate produced as described above was cut into a size of 50 mm×100 mm, and half of the laminate, having a size of 50 mm×50 mm square, was covered with a black vinyl tape (light shielding tape) Super 88 (manufactured by 3M Company) from the base material side to produce a UV light resistance test sample. A portion which was not shielded from light was distinguished as a bright portion, and a portion which was shielded from light was distinguished as a dark portion.

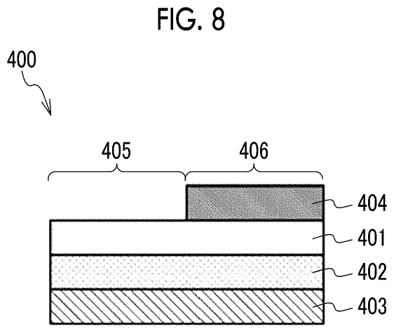

FIG. 8 shows a schematic view of each of a UV light resistance test sample 400. The UV light resistance test sample 400 had a cured layer 401, a silver nanowire layer 402, a base material 403, and a light shielding tape 404. The bright portion is represented by the reference numeral 405, and the dark portion is represented by the reference numeral 406.

A surface electrical resistance of the silver nanowire layer before and after the UV irradiation was measured using a non-contact surface electrical resistance measuring instrument EC-80P (manufactured by NAPSON). In the measurement, a probe of EC-80P was pressed from the side of the cured layer for measurement. Each of six locations of the bright portions and the dark portions was marked, and the same location was measured before and after the UV irradiation.

The UV irradiation was performed using a xenon weather meter X75 (manufactured by Suga Test Instruments Co., Ltd.). The inside of the tank was set to a temperature of 35° C. and a humidity of 50% RH, the irradiation was performed for 300 hours under the condition that irradiance from the light source was set to 0.8 W/m² (420 nm). The UV light was applied to the UV light resistance test sample from the base material and the light shielding tape side. A black panel temperature (BPT) during the test was 52° C.

The rate of increase in surface electrical resistance before and after the UV irradiation was determined, and the evaluation was carried out based on the following evaluation standard.

The results are shown in Table 4.

### (Evaluation Standard)

A: rate of increase in surface electrical resistance was 3% or less.
B: rate of increase in surface electrical resistance was more than 3% and 5% or less.
C: rate of increase in surface electrical resistance was more than 5% and 10% or less.
D: rate of increase in surface electrical resistance was more than 10%.

### —Moisture-Heat Resistance Test—

The laminate produced as described above was cut into a size of 50 mm×100 mm. A moisture-heat resistance durability test was performed in which the cut laminate was marked at 8 locations and put into a constant temperature and humidity device set to 65° C. and a humidity of 90% RH for 500 hours. A rate of increase in surface electrical resistance of the marking portion before and after the moisture-heat resistance durability test was determined, and the evaluation was carried out based on the following evaluation standard. The results are shown in Table 4.

### (Evaluation Standard)

A: rate of increase in surface electrical resistance was 3% or less.
B: rate of increase in surface electrical resistance was more than 3% and 5% or less.
C: rate of increase in surface electrical resistance was more than 5% and 10% or less.
D: rate of increase in surface electrical resistance was more than 10%.

TABLE 4

| | Interlayer | | Photosensitive layer | | Blocked isocyanate compound | | | Content of | | Moisture- |
|---|---|---|---|---|---|---|---|---|---|---|
| | Composition | Thick- | Photo- | Thick- | contained in photosensitive | | Storage | halide ion | UV light | heat |
| | for inter- | ness | sensitve | ness | layer | | elastic | [ppm by | resistance | resistance |
| | layer | [μm] | composition | [μm] | Type | Content | modulus | mass] | test | test |
| Example 1 | — | | A-1 | 5.2 | Karenz AOI-SM | 5.0% | A | 2.2 ppm | C | B |
| Example 2 | — | | A-2 | 5.2 | Karenz AOI-SM | 8.0% | B | 2.8 ppm | A | A |
| Example 3 | — | | A-3 | 5.2 | Karenz AOI-SM | 15.0% | B | 4.2 ppm | A | A |
| Example 4 | — | | A-8 | 5.2 | Karenz AOI-SM | 18.0% | C | 4.8 ppm | A | A |
| Example 5 | — | | A-4 | 5.2 | Karenz AOI-PAP | 8.0% | B | 4.7 ppm | B | B |
| Example 6 | — | | A-5 | 5.2 | Karenz MOI-SM | 8.0% | B | 2.8 ppm | A | A |
| Example 7 | — | | A-6 | 5.2 | Karenz AOI-AM | 8.0% | B | 4.5 ppm | B | B |
| Example 8 | B-1 | 1.3 | A-2 | 5.2 | Karenz AOI-SM | 8.0% | B | 2.8 ppm | A | A |
| Example 9 | B-1 | 1.3 | A-5 | 5.2 | Karenz MOI-SM | 8.0% | B | 2.8 ppm | A | A |
| Comparative | — | | A-7 | 5.2 | | 8.0% | A | 1.2 ppm | D | C |
| Example 1 | | | | | | | | | | |
| Comparative | — | | A-9 | 5.2 | Karenz AOI-BP | 8.0% | B | 6.0 ppm | D | C |
| Example 2 | | | | | | | | | | |
| Comparative | — | | A-10 | 5.2 | DURANATE TPA-B80E | 8.0% | B | | D | D |
| Example 3 | | | | | | | | | | |

The disclosure of Japanese Patent Application No. 2022-212020 filed on Dec. 28, 2022 is incorporated in the present specification by reference.

All documents, patent applications, and technical standards described in the present specification are herein incorporated by reference to the same extent that each individual document, patent application, or technical standard was specifically and individually indicated to be incorporated by reference.

### EXPLANATION OF REFERENCES

10: photosensitive transfer material
12: temporary support
16: protective film
18, 18A: photosensitive layer (metal conductive material protective film, resin layer)
20: antistatic layer
32: base material
56: lead wire
70: first metal conductive material
72: second metal conductive material
74: image display region
75: image non-display region
90: touch panel
112: first island-shaped electrode portion
114: second island-shaped electrode portion
116: first wiring part
118: second wiring part (bridge wire)
120: through hole
124: transparent substrate (transparent film substrate)
130: protective layer
132: overcoat layer
134: first electrode pattern
136: second electrode pattern
200: touch panel
400: UV light resistance test sample
401: cured layer
402: silver nanowire layer
403: substrate
404: light shielding tape
405: bright portion
406: dark portion
P: extending direction of first electrode pattern
Q: extending direction of second electrode pattern

What is claimed is:

1. A photosensitive composition comprising:
a blocked isocyanate compound,
wherein a blocked group of the blocked isocyanate compound includes an aromatic ring, and
the aromatic ring is bonded to a carbonyl group included in the blocked isocyanate compound through an oxygen atom.

2. The photosensitive composition according to claim 1,
wherein the blocked isocyanate compound has a polymerizable group.

3. The photosensitive composition according to claim 1,
wherein the aromatic ring is a benzene ring.

4. The photosensitive composition according to claim 1,
wherein the blocked isocyanate compound has a structure represented by General Formula (1), 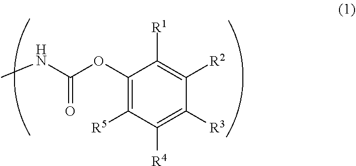
in General Formula (1),
R¹ to R⁵ each independently represent a hydrogen atom, an alkyl group, an alkoxy group, or an alkoxycarbonyl group.

5. The photosensitive composition according to claim 1,
wherein the blocked isocyanate compound is represented by General Formula (2), 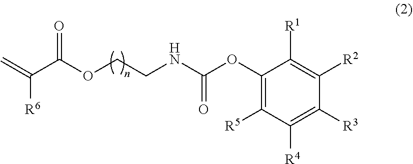
in General Formula (2),
R¹ to R⁵ each independently represent a hydrogen atom, an alkyl group, an alkoxy group, or an alkoxycarbonyl group,
R⁶ represents a hydrogen atom, an alkyl group, or an alkoxy group, and
n represents an integer of 0 to 10.

6. The photosensitive composition according to claim 1,
wherein a content of the blocked isocyanate compound is 3% by mass to 20% by mass with respect to a total solid content of the photosensitive composition.

7. The photosensitive composition according to claim 1,
wherein the photosensitive composition contains no halide ion, or
the photosensitive composition contains a halide ion and a content of the halide ion is 5.0 ppm by mass with respect to a total solid content of the photosensitive composition.

8. The photosensitive composition according to claim 1, further comprising:
a binder polymer;
a polymerizable compound; and
a polymerization initiator.

9. The photosensitive composition according to claim 8,
wherein the binder polymer includes a resin having a carboxy group.

10. The photosensitive composition according to claim 9,
wherein the binder polymer includes a (meth)acrylic resin having a carboxy group.

11. The photosensitive composition according to claim 4,
wherein the photosensitive composition contains a binder polymer, a polymerizable compound, and a polymerization initiator, and
the binder polymer includes a (meth)acrylic resin having a carboxy group.

12. A cured film obtained by curing the photosensitive composition according to claim 1.

13. A photosensitive transfer material comprising:
a temporary support; and
a photosensitive layer containing the photosensitive composition according to claim 1.

14. A laminate comprising, in the following order:
a substrate having a surface on which a layer containing a metal is provided; and
the cured film according to claim 12.

15. The laminate according to claim 14,
wherein the laminate is a touch panel.

16. The photosensitive composition according to claim 4,
wherein, in General Formula (1), R¹ in R¹ to R⁵ is an alkyl group, an alkoxy group, or an alkoxycarbonyl group.

17. The photosensitive composition according to claim 4,
wherein a content of the blocked isocyanate compound is 3% by mass to 20% by mass with respect to a total solid content of the photosensitive composition, and
wherein, in General Formula (1), R¹ in R¹ to R⁵ is an alkyl group, an alkoxy group, or an alkoxycarbonyl group.

18. The photosensitive composition according to claim 1,
wherein a content of the blocked isocyanate compound is 6% by mass to 16% by mass with respect to a total solid content of the photosensitive composition.
